(19) United States
(12) Patent Application Publication
(10) Pub. No.: US 2026/0223443 A1
(43) Pub. Date: Jul. 30, 2026

(54) SEMICONDUCTOR DEVICE GATE STRUCTURE

(71) Applicant: Taiwan Semiconductor Manufacturing Company, Ltd., Hsinchu (TW)

(72) Inventors: Tefu Yeh, Kaohsiung City (TW); Jo-Chun Hung, Hsinchu City (TW); Ying-Liang Chuang, Zhubei City (TW); Chun-Cheng Chou, Taichung City (TW)

(73) Assignee: Taiwan Semiconductor Manufacturing Company, Ltd., Hsinchu (TW)

(21) Appl. No.: 19/036,410

(22) Filed: Jan. 24, 2025

(51) Int. Cl. H10D 84/83; H01L 21/311; H01L 21/3205; H01L 21/3213; H10D 30/00; H10D 30/01; H10D 30/43; H10D 62/10; H10D 64/27

(52) U.S. Cl. CPC H10D 84/83135; H10D 30/014; H10D 30/0191; H10D 30/43; H10D 30/501; H10D 62/121; H10D 64/516; H10D 84/8314; H10D 84/832; H10P 14/40; H10P 50/283; H10P 50/667

(57) ABSTRACT

A semiconductor device and a method of fabricating the semiconductor device are disclosed. The method includes forming a first set of nanostructured channel layers and a second set of nanostructured channel layers on a fin or sheet base, forming gate openings surrounding the first and second sets of nanostructured channel layers, forming oxide layers on exposed surfaces of the first and second sets of nanostructured channel layers and the fin or sheet base in the gate openings, forming a high-k dielectric layer on in the gate openings, forming a dummy layer in gate openings of the first set of nanostructured channel layers, depositing a work function layer in the gate openings, removing the work function layer and dummy layer from gate openings surrounding the first set of nanostructured channel layers, and depositing a gate metal fill layer in the gate openings.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), fin field effect transistors (finFETs), and gate-all-around (GAA) FETs. Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device with different gate structures, in accordance with some embodiments.

FIGS. 1B-1D illustrate cross-sectional views of a semiconductor device with different gate structures, in accordance with some embodiments.

FIG. 2 is a flow diagram of a method for fabricating a semiconductor device with different gate structures, in accordance with some embodiments.

FIGS. 3A-20A, 3B-20B, 10C-20C, 15D, 16D, and 15E illustrate cross-sectional views of a semiconductor device with different gate structures at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

A threshold voltage of a field effect transistor (FET) is the minimum voltage required to create a conducting channel between a source and drain of the FET. Integrated circuits can include both n-type FETs (nFETs) and p-type FETs (pFETs), which can have different threshold voltages. To achieve different threshold voltages, the NFETs and PFETs can have different gate electrodes (also referred to as “gate structures”) to form FETs with different threshold voltages. A gate electrode can include a work function layer disposed between a dielectric layer and a gate metal fill layer. The dielectric layer can be a high-k dielectric layer. A thickness of the work function layer affects the threshold voltage of the FET. As an alternative to having different thicknesses of the work function layer for the NFET and the PFET, the NFET gate electrode can be formed without a work function layer while the PFET gate electrode can have a work function layer. In a gate-all-around FET (GAA FET), forming the work function layer only on the p-type GAA FET requires depositing the work function layer and patterning the work function layer on nanostructured channel layers forming the n-type GAA FET (also referred to as “NFET”) and p-type GAA FET (also referred to as “PFET”), and selectively removing the work function layer from the n-type GAA FET. However, removing the work function layer deposited in gate openings between adjacent nanostructured channel layers forming the n-type GAA FET can be challenging. For example, a first challenge can be an inability of a work function layer etchant to reach the work function layer deposited in gate openings between nanostructured channel layers of the NFET due to a spacing constraint, which continues to get smaller with scaling down of GAA FETs. To address this challenge, the present disclosure describes a method of forming an NFET gate electrode by using a dummy layer. The dummy layer is deposited between nanostructured channel layers of the NFET to prevent the work function metal (WFM) layer from depositing in spaces between the nanostructured channel layers.

A second challenge is that the dummy layer deposited in gate openings between nanostructured channel layers can enclose an air gap. During a dummy layer trim back process, end portions of the dummy layer enclosing the air gap can be removed to open up the air gap. During a subsequent WFM layer deposition operation, the WFM layer can be deposited in the air gap. The work function layer trapped in the air gap between nanostructured channel layers can be difficult to remove.

To address the above mentioned challenges, the present disclosure provides a method of forming an NFET with a gate electrode stack without a WFM layer and a PFET with a gate electrode stack with a WFM layer. The method includes forming a first set of nanostructured channel layers and a second set of nanostructured channel layers for fabricating the NFET and PFET, respectively. A dummy layer is formed between the first set of nanostructured channel layers to prevent deposition of a WFM layer between nanostructured channel layers of the first set of nanostructured channel layers in the subsequent operations. WFM layers are deposited to surround the first and second sets of nanostructured channel layers. A WFM layer surrounding the second set of nanostructured channel layers is protected using a protective layer. The WFM layer and the dummy layer surrounding the first set of nanostructured channel layers is removed. A gate metal fill layer is subsequently deposited to form gate electrodes of the NFET and PFET.

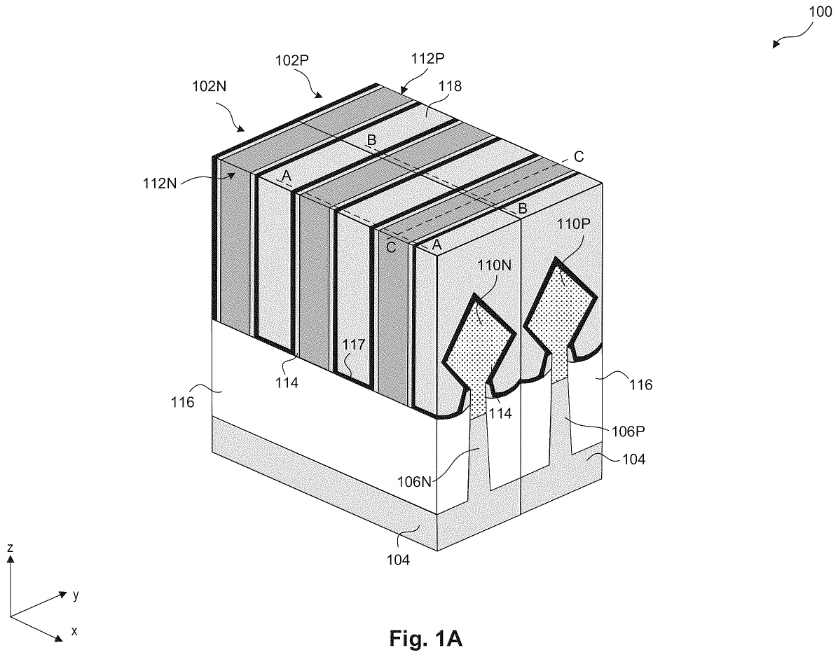

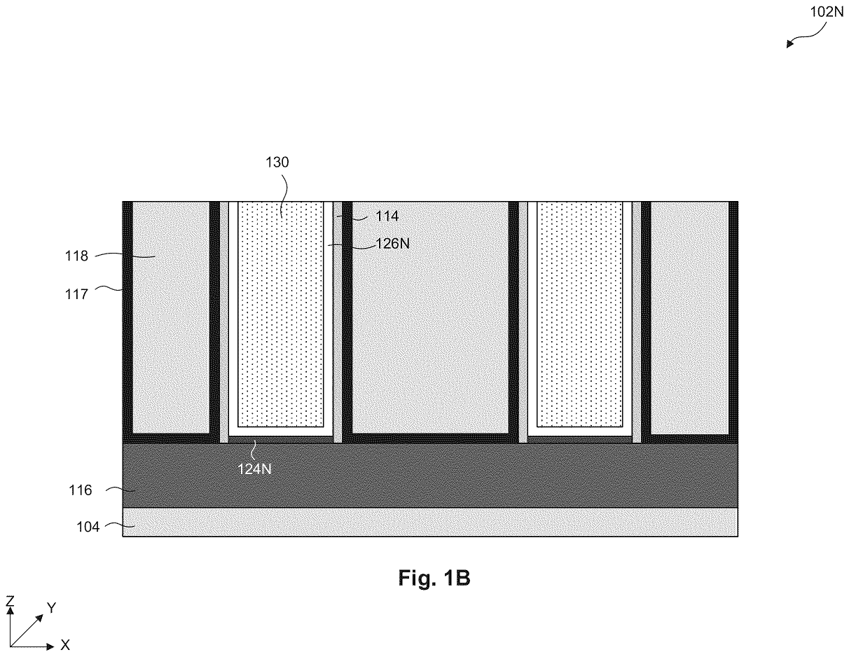

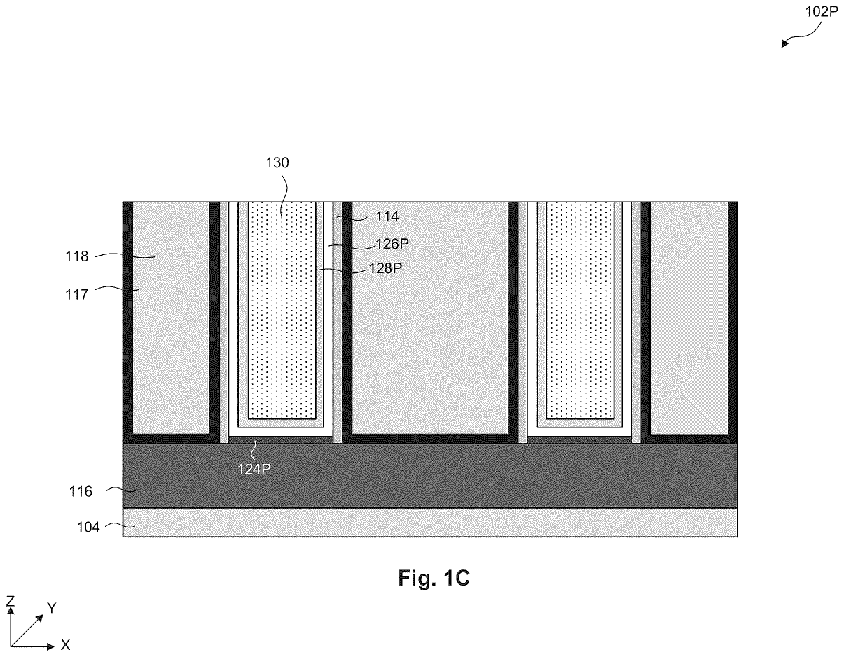

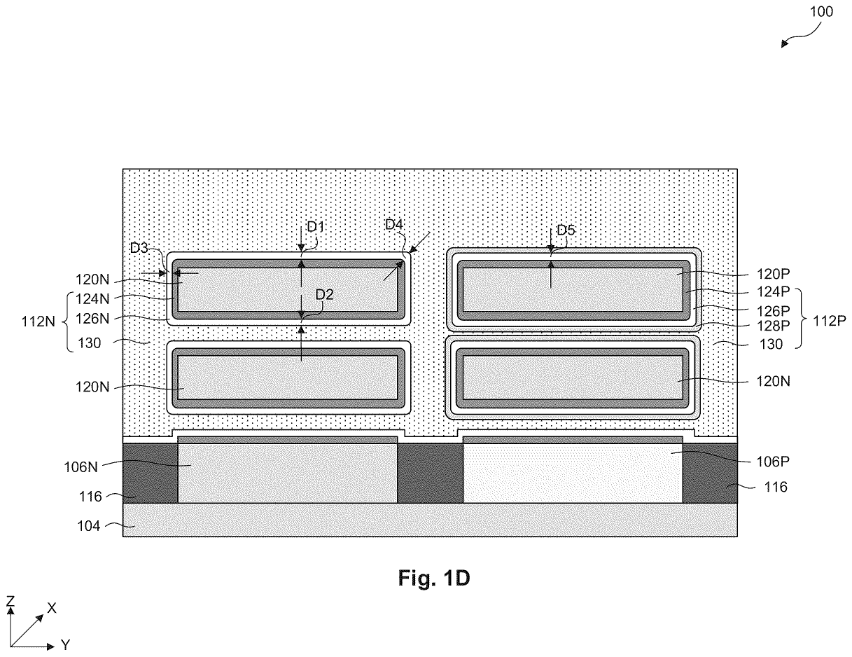

FIG. 1A illustrates an isometric view of a semiconductor device 100 with an n-type GAA FET 102N (“NFET 102N”) and a p-type GAA FET 102P (“PFET 102P”), according to some embodiments. FIG. 1B illustrates a cross-sectional view of NFET 102N along line A-A of FIG. 1A, according to some embodiments. FIG. 1C illustrates a cross-sectional view of PFET 102P along line B-B of FIG. 1A, according to some embodiments. FIG. 1D illustrates a cross-sectional view of the NFET 102N and PFET 102P along lines C-C of FIG. 1, according to some embodiments. FIGS. 1B, 1C and 1D illustrate cross-sectional views of semiconductor device 100 with additional structures that are not shown in FIG. 1A for simplicity. The discussion of elements with the same annotations applies to each other, unless mentioned otherwise.

Referring to FIGS. 1A-1D, in some embodiments, semiconductor device 100 can be formed on a substrate 104 with NFET 102N and PFET 102P formed on different regions of substrate 104. There may be other FETs and/or structures (e.g., isolation structures) formed between NFET 102N and PFET 102P on substrate 104. Substrate 104 can be a semiconductor material, such as Si, germanium (Ge), SiGe, a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). Semiconductor device 100 can further include gate spacers 114, shallow trench isolation (STI) regions 116, etch stop layers (ESLs) 117, and interlayer dielectric (ILD) layers 118. In some embodiments, gate spacers 114, STI regions 116, ESLs 117, and ILD layers 118 can include an insulating material, such as silicon oxide (SiO₂), silicon nitride (SiN), silicon carbon nitride (SiCN), silicon oxycarbon nitride (SiOCN), and silicon germanium oxide.

Referring to FIGS. 1A, 1B and 1D, in some embodiments, NFET 102N can include (i) a fin or sheet base 106N, (ii) source/drain (S/D) regions 110N disposed on fin or sheet base 106N, (iii) gate structures 112N disposed on portions of fin or sheet base 106N that are not covered by S/D regions 110N, and (iv) nanostructured channel layers 120N surrounded by gate structures 112N. Referring to FIGS. 1A, 1C and 1D, in some embodiments, PFET 102P can include (i) a fin or sheet base 106P, (ii) source/drain (S/D) regions 110P disposed on fin or sheet base 106P, (iii) gate structures 112P disposed on portions of fin or sheet base 106P that are not covered by S/D regions 110P, and (iv) nanostructured channel layers 120P surrounded by gate structures 112P. As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm. In some embodiments, nanostructured channel layers 120N and 120P can be in the form of nanosheets, nanowires, nanorods, nanotubes, or other suitable nanostructured shapes. In some embodiments, fin or sheet bases 106N and 106P can include a material similar to substrate 104 and extend along an X-axis.

In some embodiments, S/D regions 110N can include an epitaxially-grown semiconductor material, such as Si, and n-type dopants, such as phosphorus and other suitable n-type dopants. In some embodiments, S/D regions 110P can include an epitaxially-grown semiconductor material, such as Si and SiGe, and p-type dopants, such as boron and other suitable p-type dopants.

In some embodiments, nanostructured channel layers 120N and 120P can include semiconductor materials similar to or different from substrate 104. In some embodiments, nanostructured channel layers 120N and 120P can include Si, silicon arsenide (SiAs), silicon phosphide (SiP), silicon carbide (SiC), silicon carbon phosphide (SiCP), SiGe, silicon germanium boron (SiGeB), germanium boron (GeB), silicon germanium stannum boron (SiGeSnB), a III-V semiconductor compound, or other suitable semiconductor materials. Though rectangular cross-sections of nanostructured channel layers 120N and 120P are shown, nanostructured channel layers 120N and 120P can have cross-sections of other geometric shapes (e.g., circular, elliptical, triangular, or polygonal). In some embodiments, a distance between neighboring nanostructured channel layers 120N and 120P along a Z-axis can be about 8 nm to about 12 nm. In some embodiments, each of nanostructured channel layers 120N and 120P can have a thickness of about 5 nm to about 8 nm along a Z-axis. In some embodiments, each of nanostructured channel layers 120N and 120P can have a length of about 8 nm to about 70 nm along an X-axis.

In some embodiments, gate structures 112N and 112P can be multi-layered structures. In some embodiments, gate structure 112N can include (i) IL layer 124N, (ii) dielectric layer 126N disposed on IL layer 124N, and (iii) gate metal fill layer 130 disposed on dielectric layer 126N. In some embodiments, as shown in FIG. 1D, (i) a first portion of dielectric layer 126N formed on a top surface of an uppermost nanostructured channel layer 120N can have a thickness D1, (ii) a second portion of dielectric layer 126N formed on a bottom surface of nanostructured channel layers 120N can have a thickness D2, and (iii) a third portion of dielectric layer 126N formed on sidewall surfaces of nanostructured channel layers 120N can have a thickness D3. In some embodiments, thickness D1 can be less than thickness D2. In some embodiments, thickness D3 can be substantially equal to thickness D1. Thicknesses D1, D2 and D3 are measured along a Z-axis. For example, thickness D1 can be between about 1.5 nm and about 1.8 nm, thickness D2 can be between about 1.9 nm and about 2.2 nm, and thickness D3 can be between about 1.6 nm and about 1.8 nm. For example, a difference in thickness between D2 and D1 can be between about 0.1 nm and about 0.7 nm. For example, a difference in thickness between D3 and D1 can be between about 0 nm and about 0.3 nm. For example, a difference in thickness between D2 and D3 can be between about 0.1 nm and about 0.6 nm. In some, embodiments, as shown in FIG. 1D, a thickness D4 of a fourth portion of dielectric layer 126N formed on upper corners of the uppermost nanostructured channel layer 120N can be between about 1.2 nm and about 2.0 nm.

Similarly, in some embodiments, gate structure 112P can include (i) IL layer 124P, (ii) dielectric layer 126P disposed on IL layer 124P, (iii) WFM layer 128P disposed on dielectric layer 126P, and (iv) gate metal fill layer 130 disposed on WFM layers 128P. In some embodiments, as shown in FIG. 1D, a portion of dielectric layer 126P formed on a top surface of uppermost nanostructured channel layer 120P can have a thickness D5. In some embodiments, a thickness D5 can be substantially equal to a thickness D1. In some embodiments, thickness D5 can range between about 1.2 nm and about 1.5 nm. Thickness D5 is measured along a Z-axis.

In some embodiments, WFM layer 128P of gate structures 112P can include substantially Al-free (e.g., with no Al) metals, metal nitrides, or metal alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, tantalum copper (Ta—Cu), molybdenum nitride (MoN), tungsten nitride (WN), tungsten carbon nitride (WCN), cobalt nitride (CON), and W. In some embodiments, WFM layer 128P can be formed of TiN with a thickness between about 28 Å and about 35 Å.

In some embodiments, gate metal fill layer 130 can be formed of a suitable conductive material, such as tungsten (W), titanium (Ti), silver (Ag), ruthenium (Ru), molybdenum (Mo), copper (Cu), cobalt (Co), aluminum (Al), iridium (Ir), nickel (Ni), metal alloys, and a combination thereof.

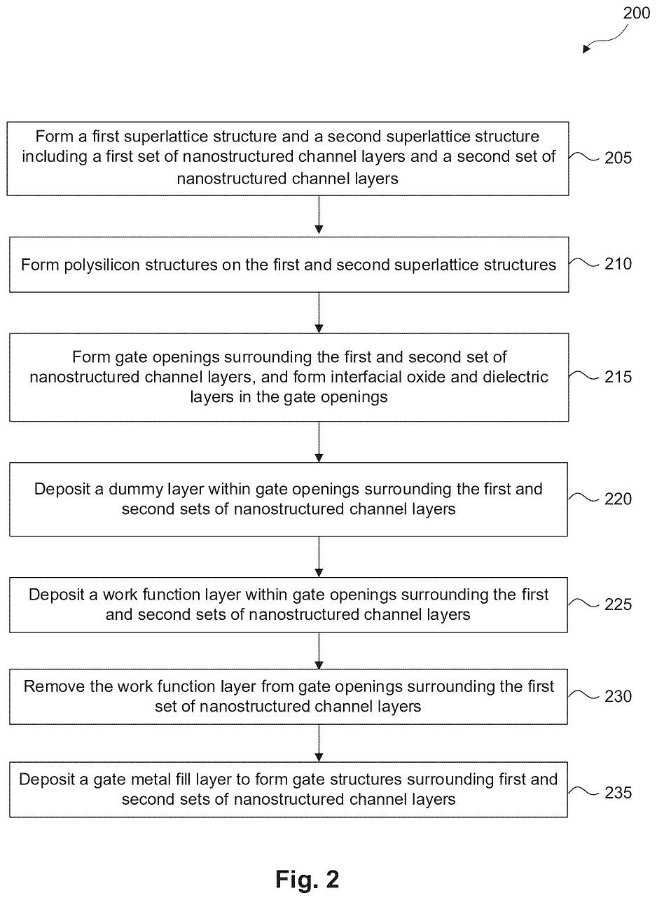

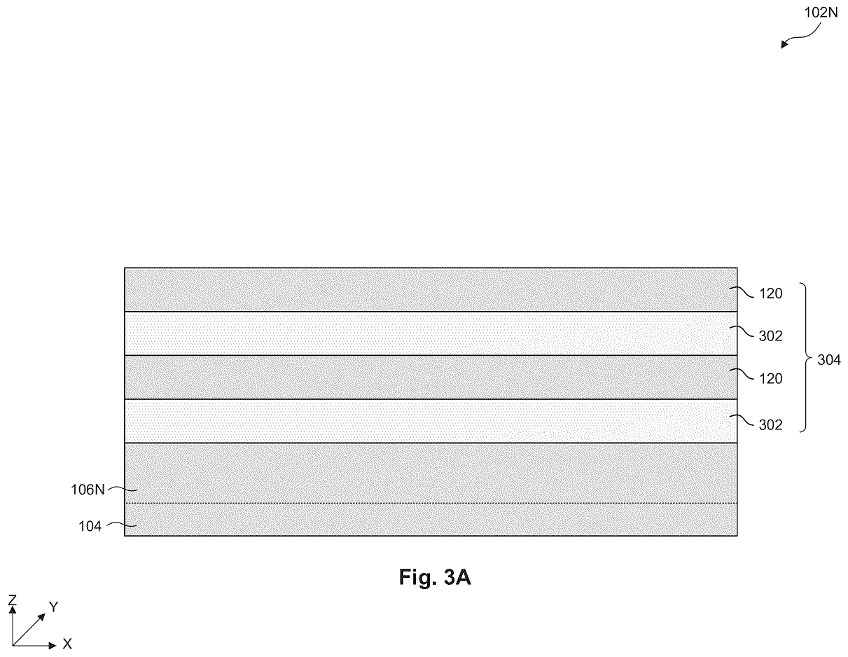

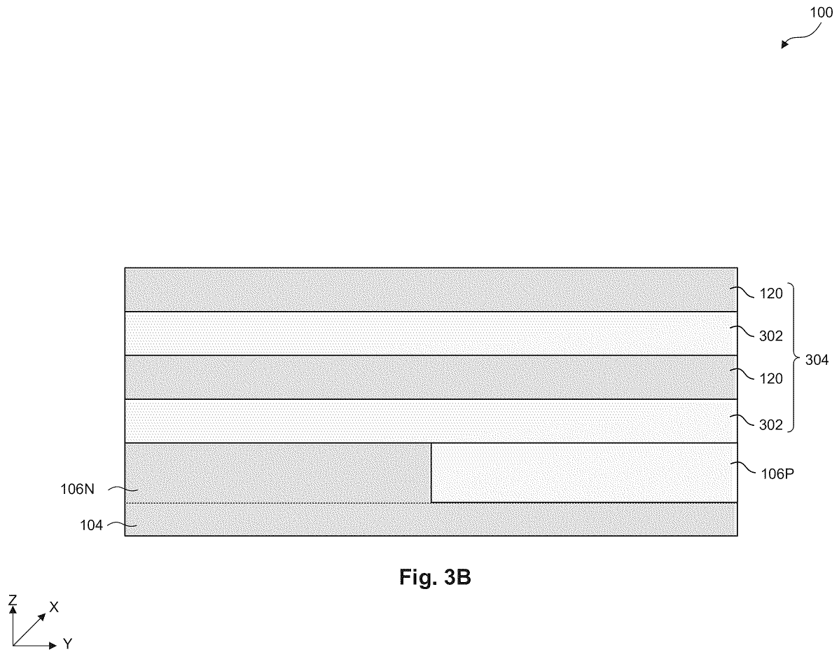

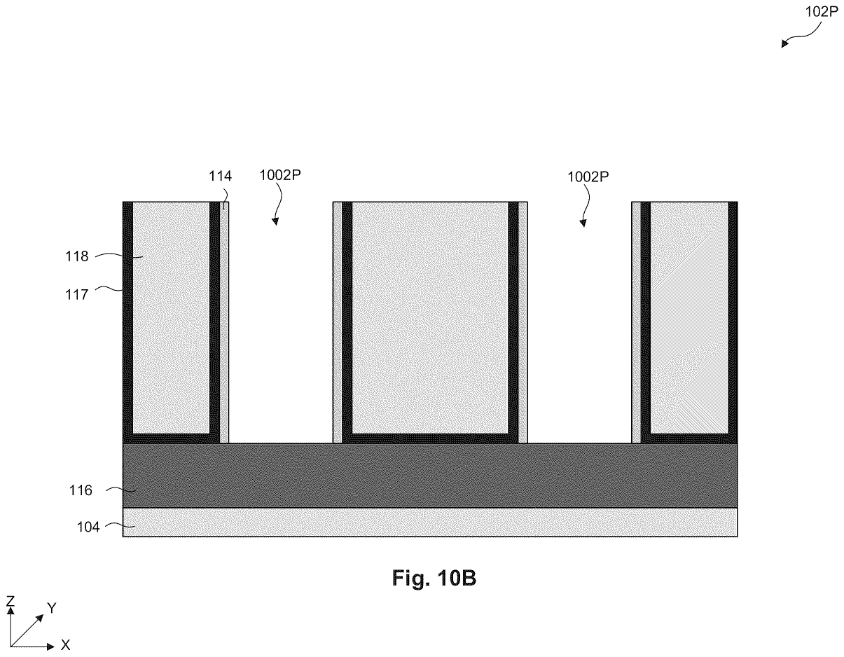

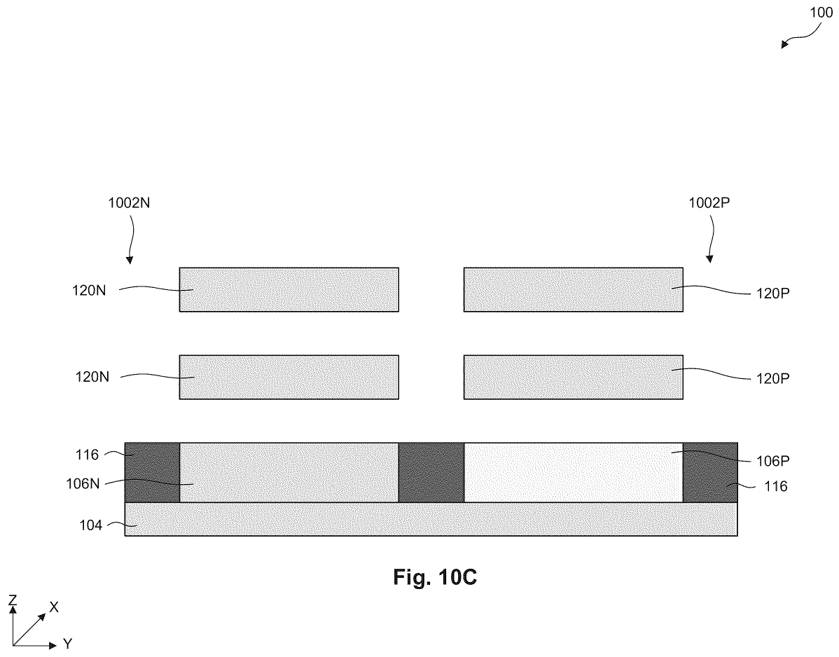

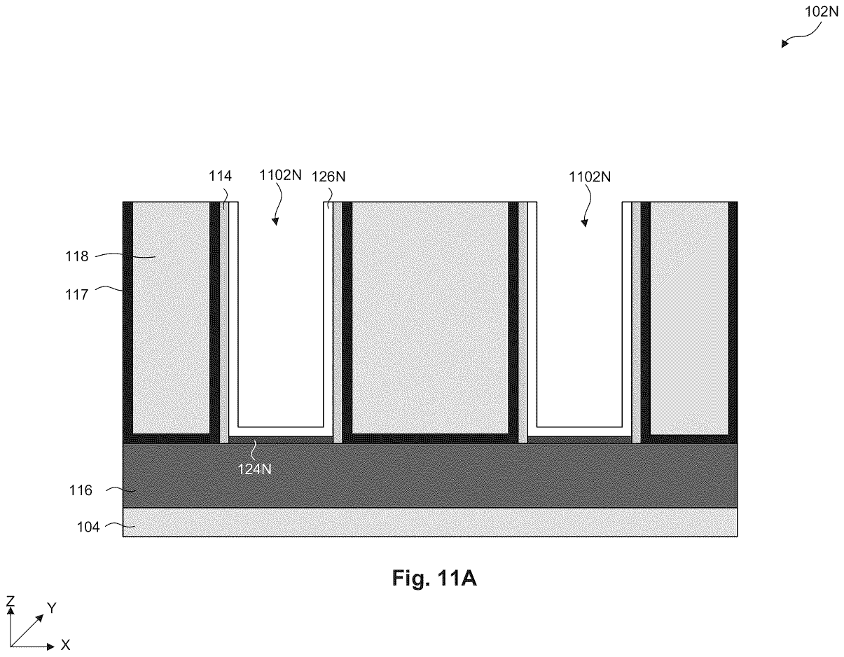

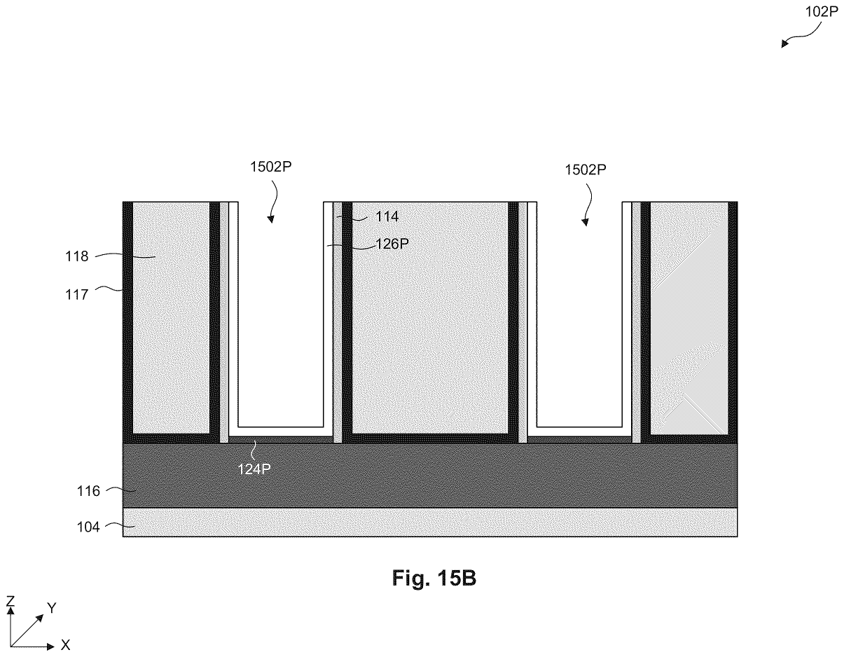

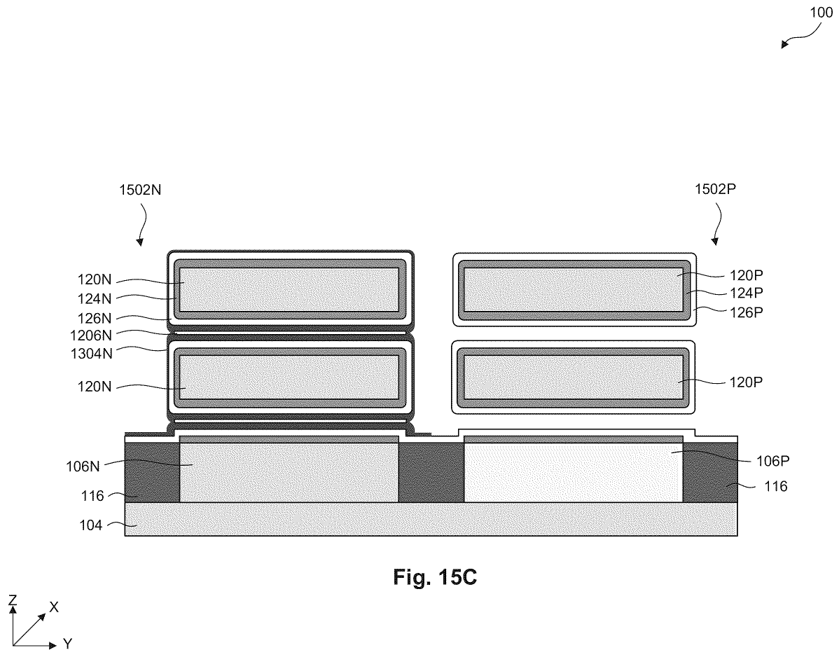

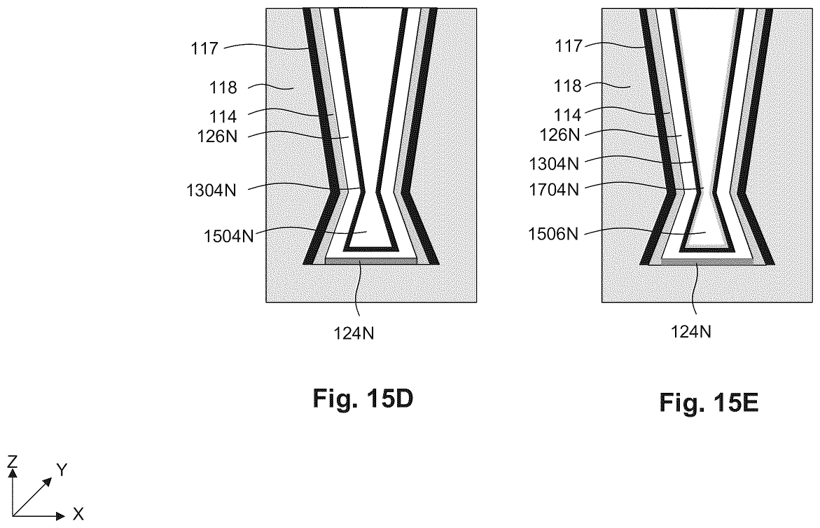

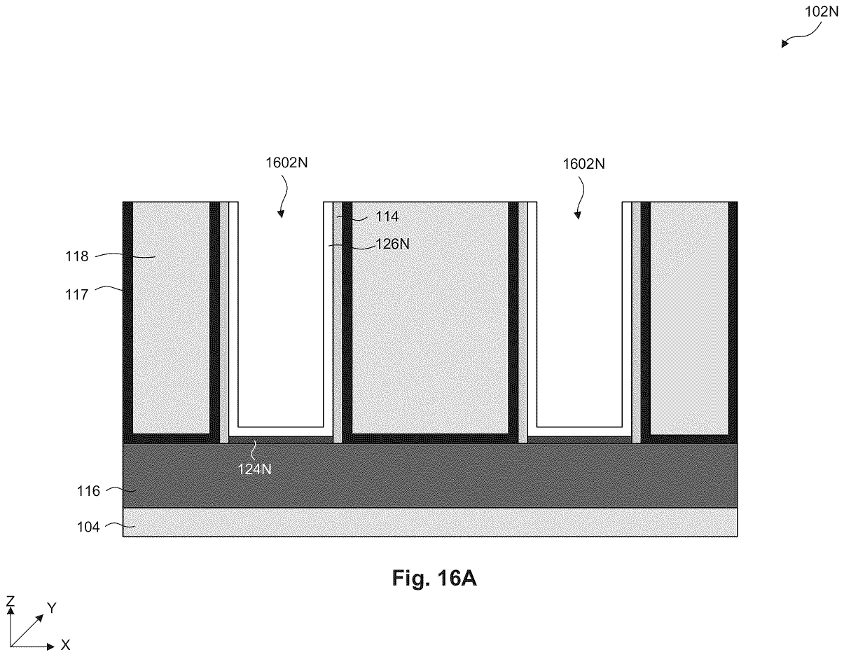

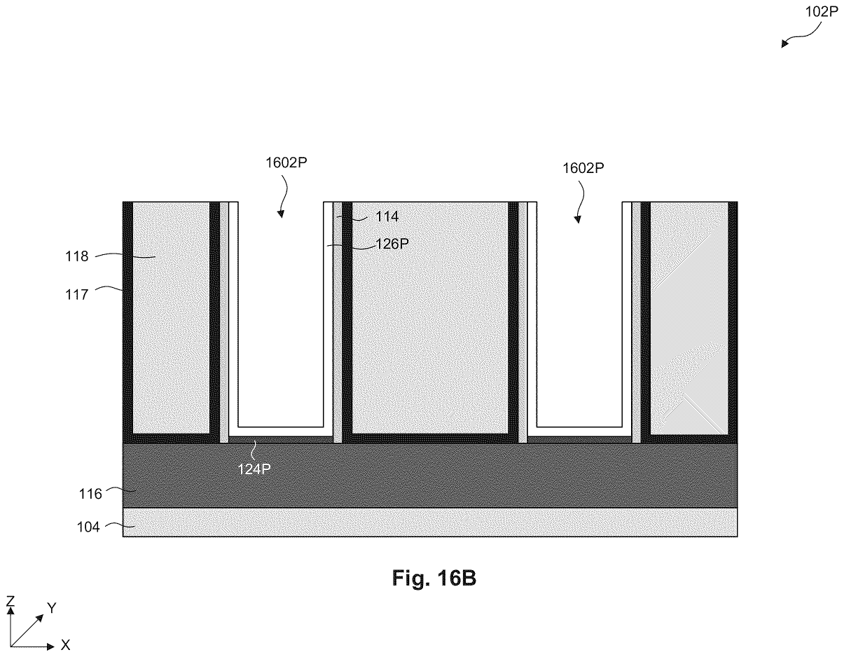

FIG. 2 is a flow diagram of an example method 200 for fabricating NFET 102N and PFET 102P with cross-sectional views shown in FIGS. 1B-1D, according to some embodiments. For illustrative purposes, the operations illustrated in FIG. 2 will be described with reference to the example fabrication process for fabricating NFET 102N and PFET 102P as illustrated in FIGS. 3A-20C. FIGS. 3A-20A are cross-sectional views of NFET 102N along line A-A of FIG. 1A, and FIGS. 10B-20B are cross-sectional views of PFET 102P along line B-B of FIG. 1A at various stages of fabrication, according to some embodiments. FIGS. 15D and 15E are cross-sectional views of a gate structure of NFET 102N along line A-A of FIG. 1A at various stages of fabrication, according to some embodiments. FIGS. 3B-9B and 10C-20C are cross-sectional views of NFET 102N and PFET 102P along line C-C of FIG. 1A at various stages of fabrication, according to some embodiments. Operations can be performed in a different order or not performed depending on specific applications. It should be noted that method 200 may not produce a complete NFET 102N and PFET 102P. Accordingly, it is understood that additional processes can be provided before, during, and after method 200, and that some other processes may only be briefly described herein. Elements in FIGS. 3A-20A, 3B-20B, 10C-20C, 15D, and 15E use the same annotations as elements in FIGS. 1A-1D are described above.

Referring to FIG. 2, in operation 205, a superlattice structure is formed on a first fin base and a second fin base (or sheet base). The superlattice structure formed on the first fin base includes a first set of nanostructured channel layers. The first superlattice structure can be used to form the NFET. The superlattice structure formed on the second fin base includes a second set of nanostructured channel layers. The second superlattice structure can be used to form the PFET. For example, as shown in FIGS. 3A and 3B, superlattice structure 304 is formed on fin or sheet bases 106N and 106P. Superlattice structure 304 can include nanostructured layers 120 and 302 arranged in an alternating configuration. In some embodiments, nanostructured layer 302 can include materials different from nanostructured layer 120. Nanostructured layer 302 is also referred to as “sacrificial layer 302.”

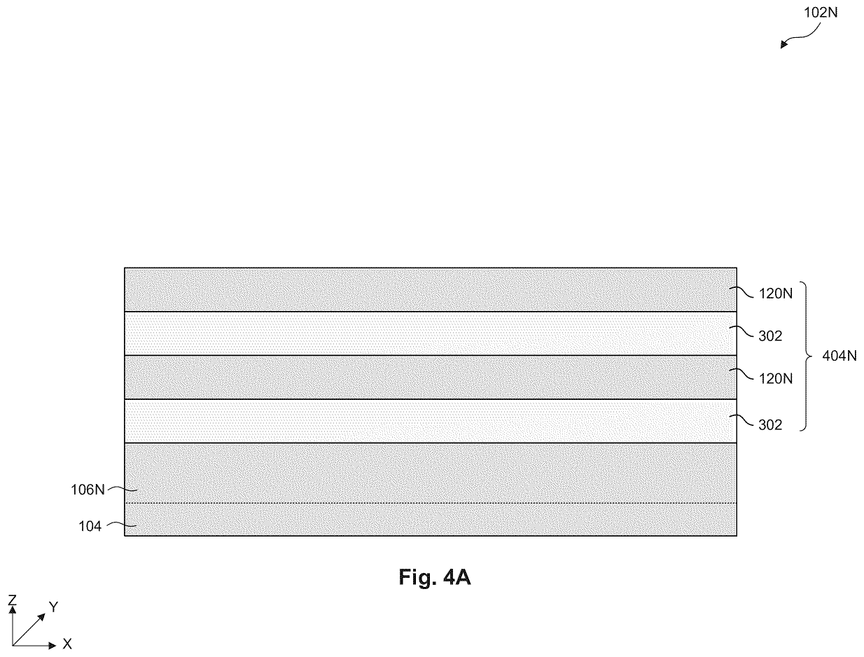

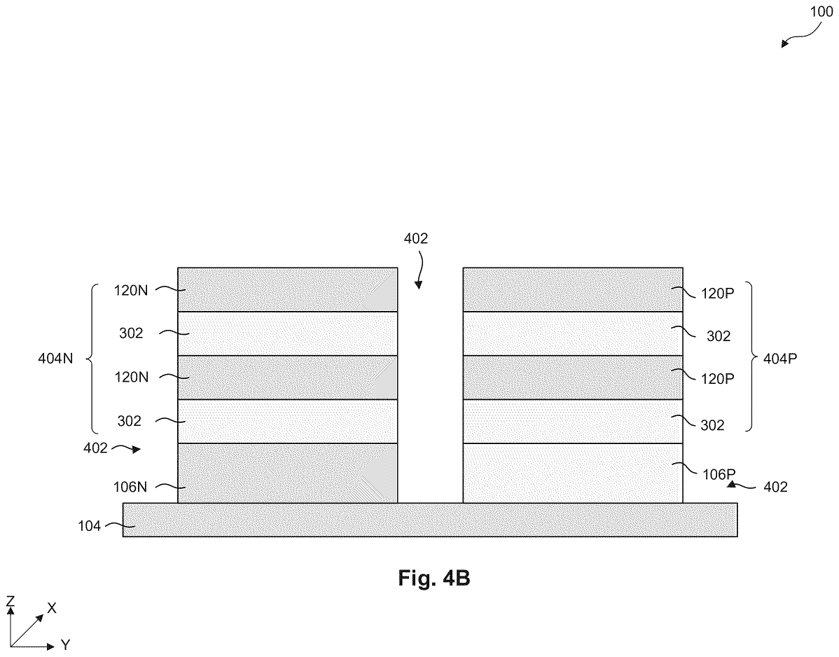

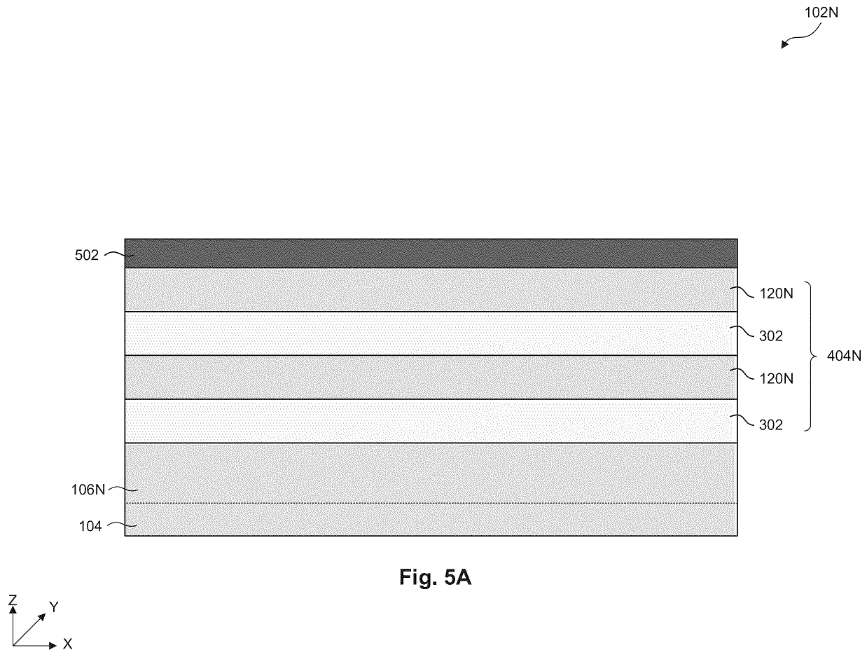

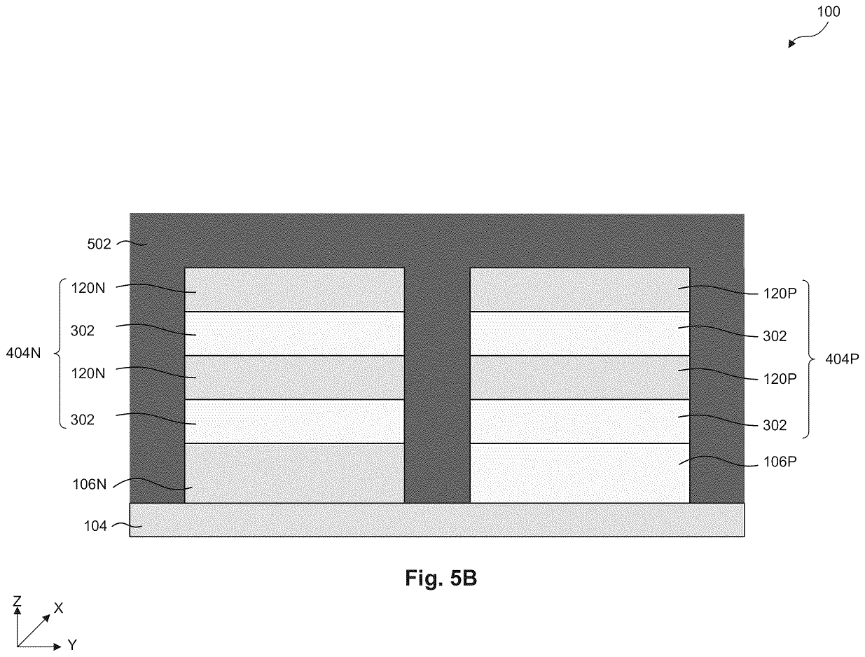

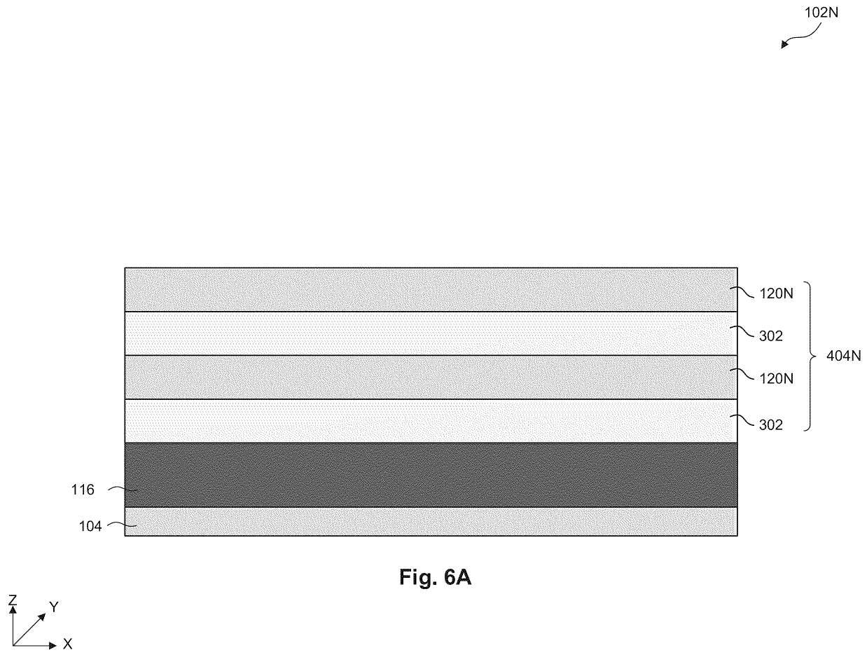

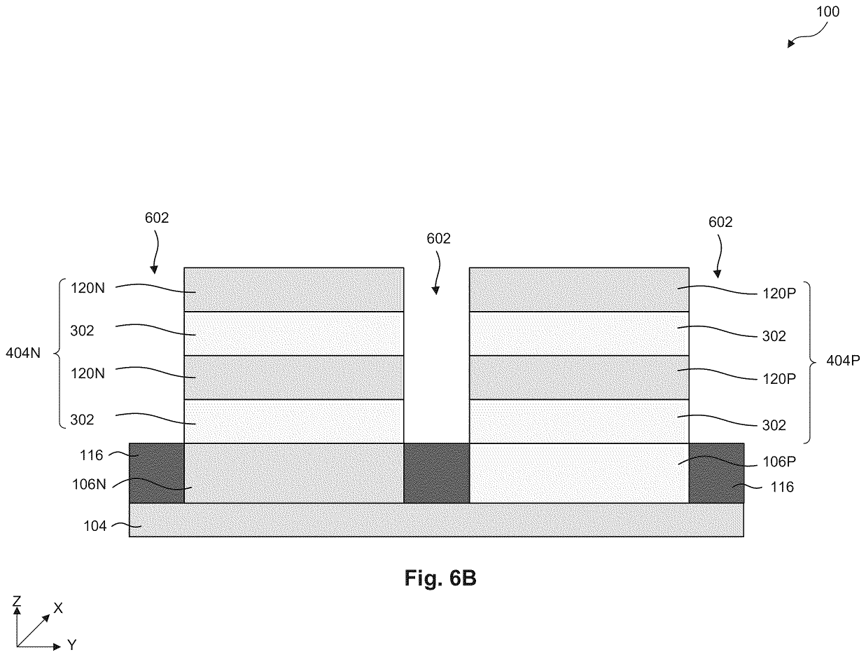

Portions of the superlattice structure and fin bases are removed to form the first and second superlattice structures for forming the NFET and PFET. The first and second superlattice structures can be separated by openings for isolation regions. For example, as illustrated in FIG. 4B, portions of superlattice structure 304 and fin bases 106N and 106P can be etched to form first superlattice structure 404N and second superlattice structure 404P. Superlattice structures 404N and 404P are separated by opening 402. As shown in FIGS. 4A and 4B, first superlattice structure 404N includes nanostructured channel layers 120N (also referred to as “first set of nanostructured channel layers”) and sacrificial layers 302 arranged in an alternating configuration. Sheet base 106P is not visible in cross-sectional view in FIG. 4A. Similarly, as shown in FIG. 4B, second superlattice structure 404P includes nanostructured channel layers 120P (also referred to as “second set of nanostructured channel layers”) and sacrificial layers 302 arranged in an alternating configuration. Subsequent to formation of openings 402, STI layer 502 can be blanket deposited on structures shown in FIGS. 4A and 4B to form structures shown in FIGS. 5A and 5B. STI layer 502 can be recessed to form openings 602 and STI regions 116 as shown in FIGS. 6A and 6B.

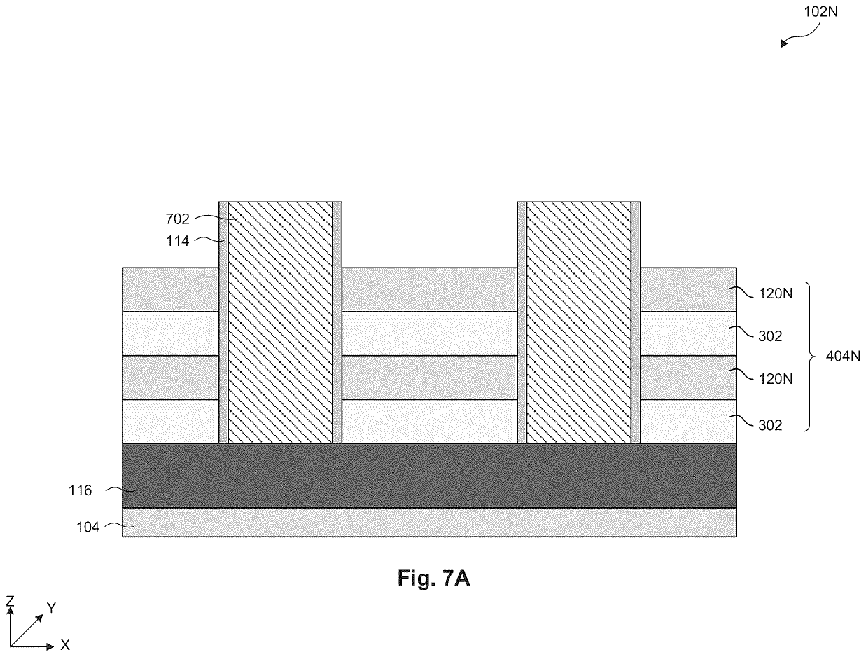

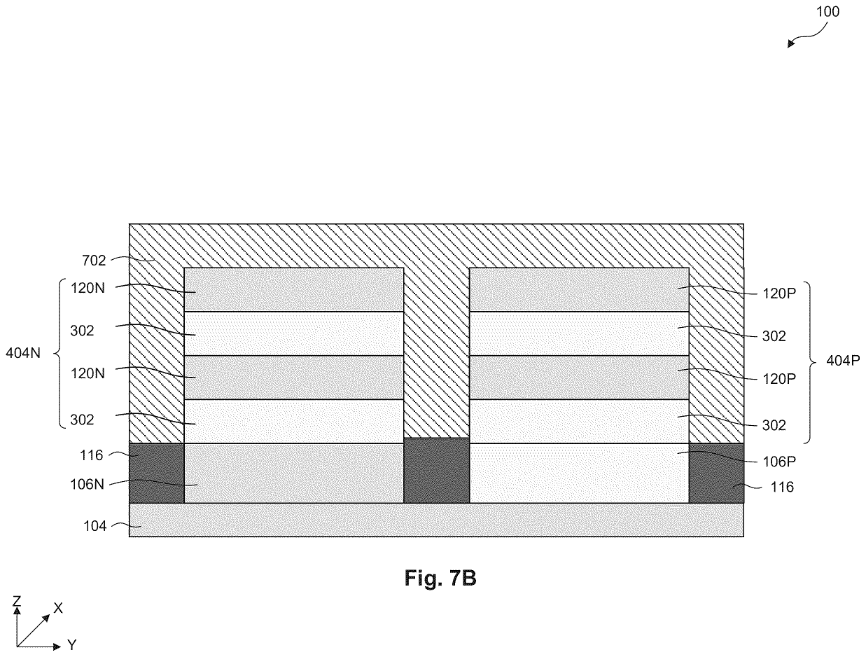

Referring to FIG. 2, in operation 210, polysilicon structures are formed on the first and second superlattice structures. For example, as shown in FIGS. 7A and 7B, polysilicon structure 702 can be epitaxially formed on superlattice structures 404N and 404P. Outer gate spacer 114 can be formed on either side of polysilicon structure 702. Outer gate spacer 114 is not visible in the cross-section in FIG. 7B. During subsequent processing, polysilicon structure 702 can be replaced in a gate replacement process to form gate structures 112N and 112P.

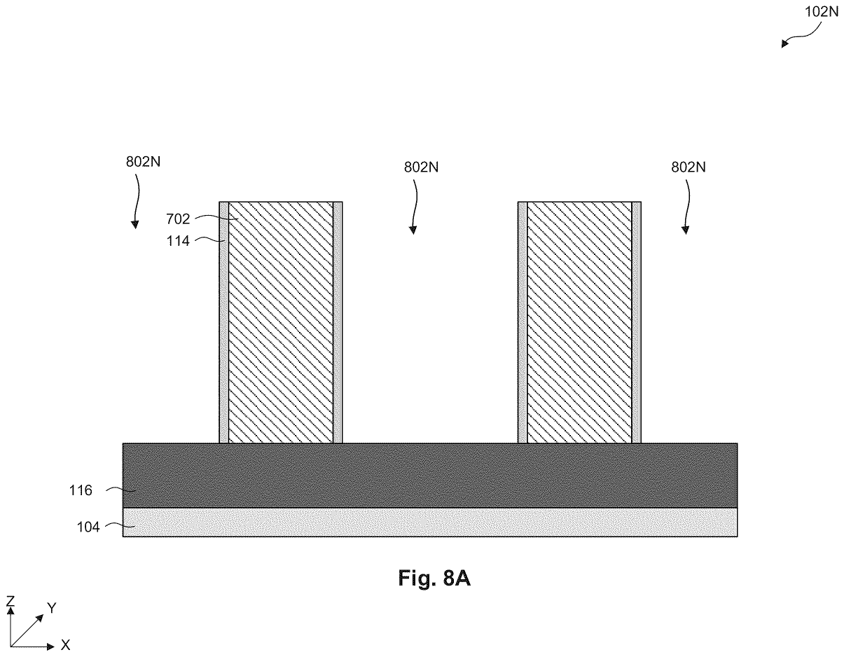

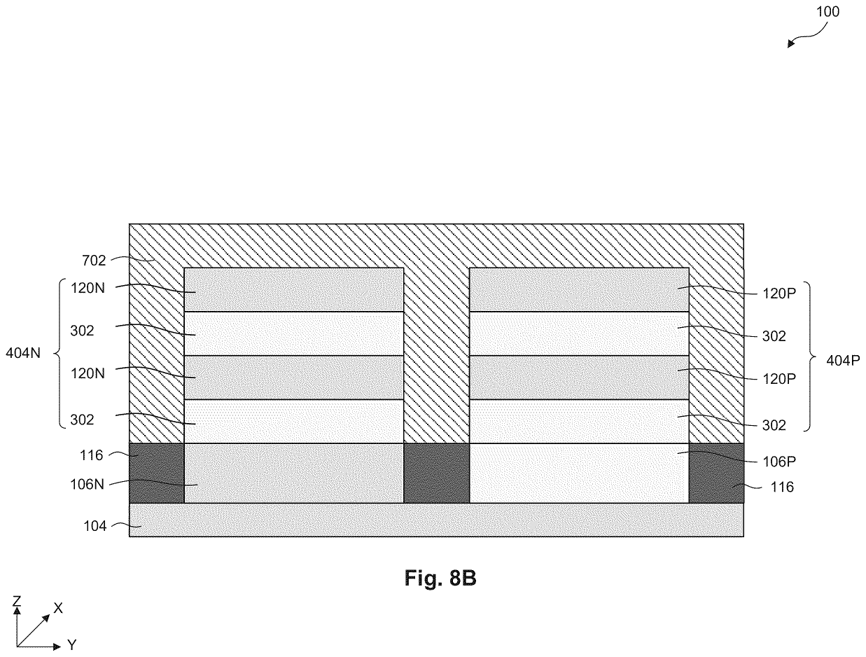

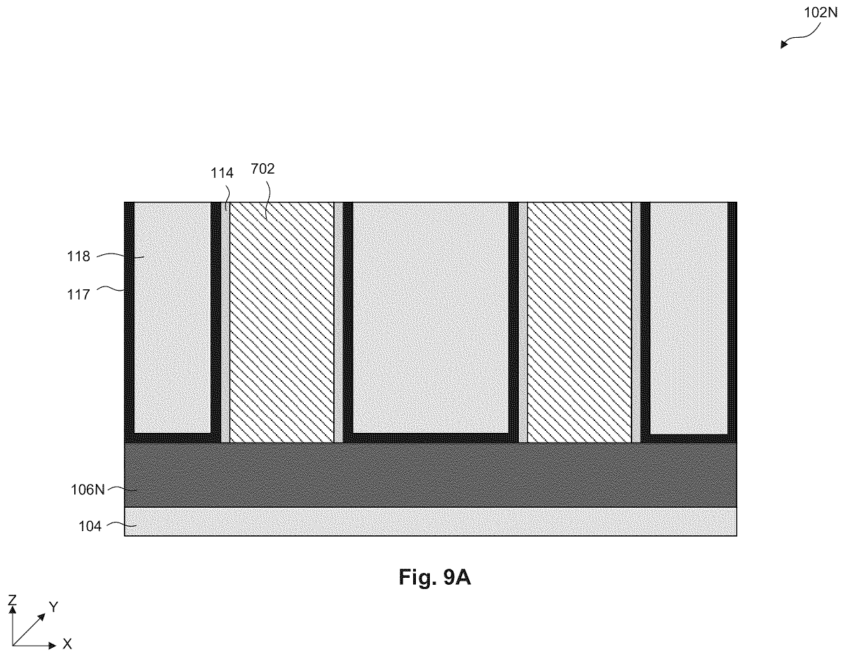

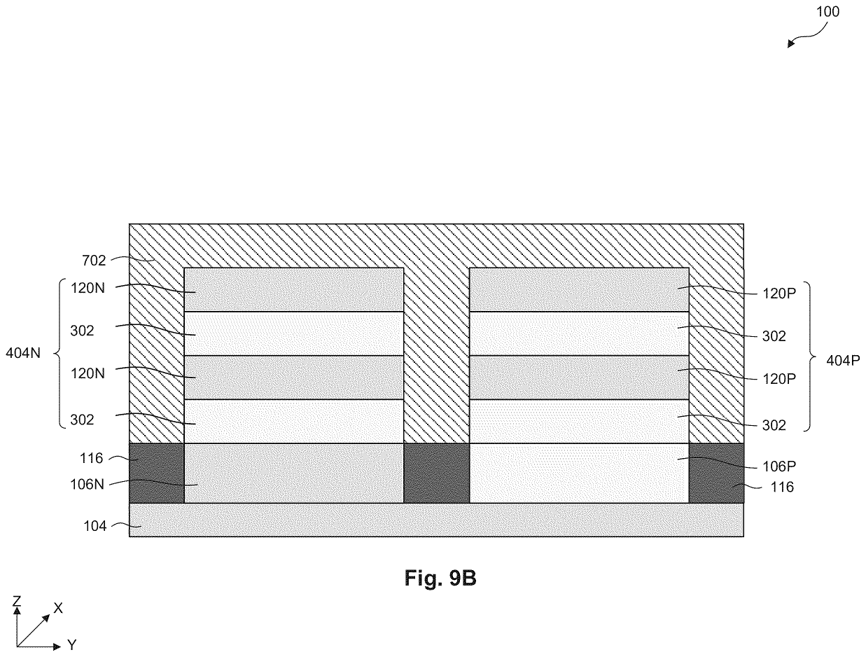

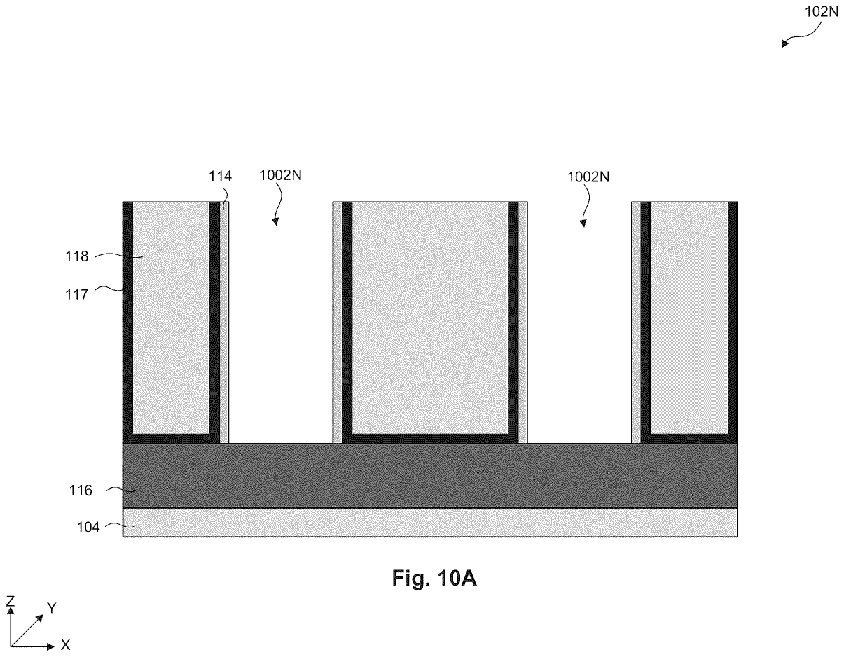

S/D regions are formed on the fin or sheet bases. For example, the formation of S/D regions can include sequential operations of (i) forming S/D openings 802N, through superlattice structure 404N, on portions of sheet base 106N that are not underlying polysilicon structures 702, as shown in FIG. 8A, and (ii) epitaxially growing n-type or p-type semiconductor materials in S/D openings 802N as shown in FIG. 9A. S/D regions are not visible in the cross-sectional views of FIGS. 8B and 9B. After the formation of S/D regions, ESL 117 and ILD layer 118 can be formed on S/D regions to form the structure of FIG. 9A. ESL 117 and ILD layer 118 are not visible in the cross-sectional view of FIG. 9B.

In some embodiments, inner gate spacers (not shown) can be formed between operations (i) and (ii) of the formation process of epitaxial S/D regions 110N and 110P. The formation of inner gate spacers can include sequential operations of (i) etching end portions of nanostructured layers 302 along an X-axis to form recesses, (ii) depositing an insulating material in the recesses and on sidewalls of nanostructured channel layers 120N, 120P, and nanostructured layers 302, and (iii) etching the deposited insulating material to form inner gate spacers.

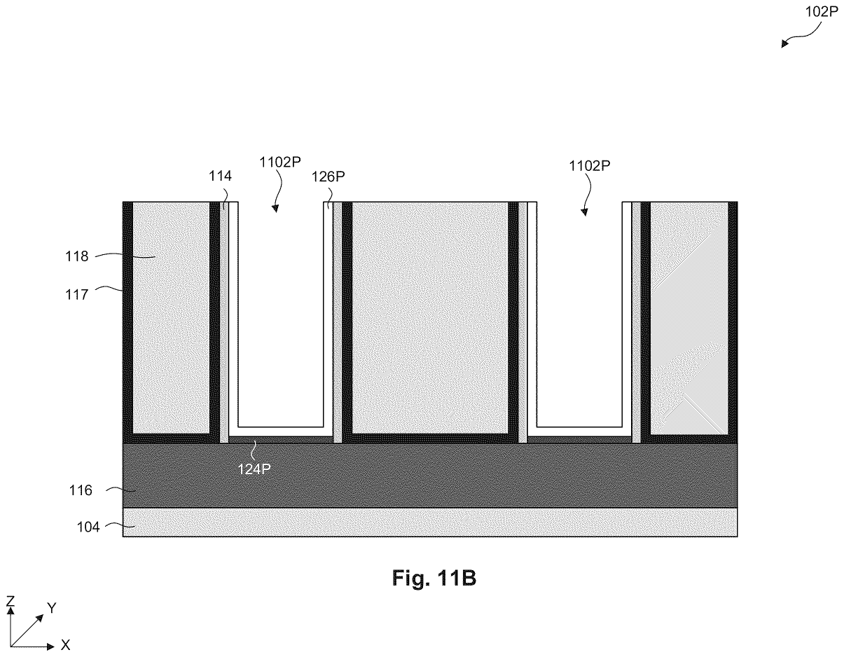

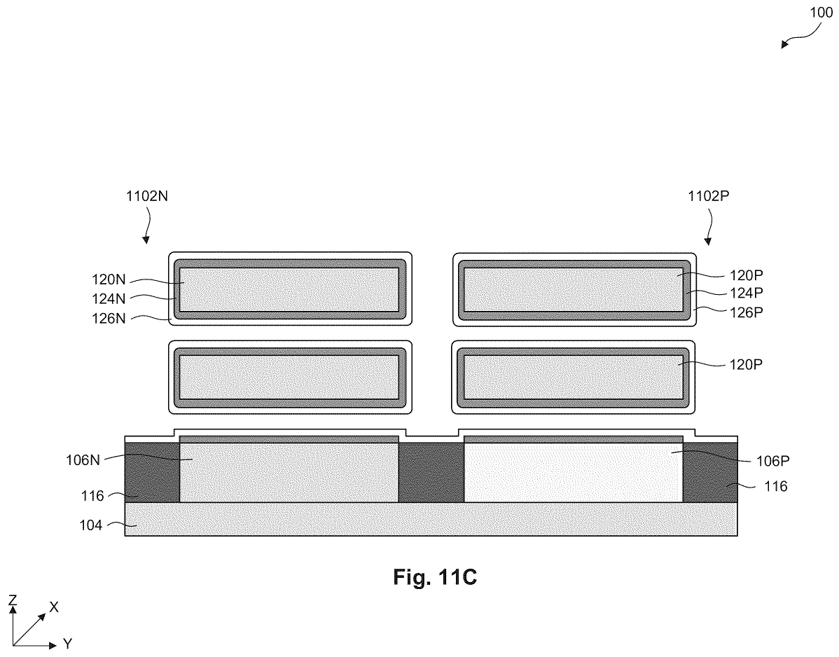

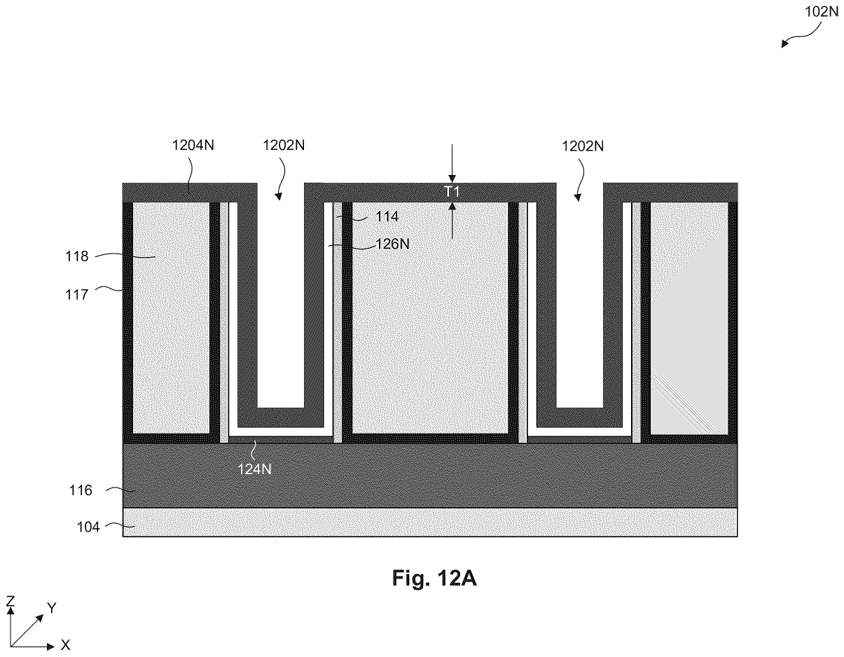

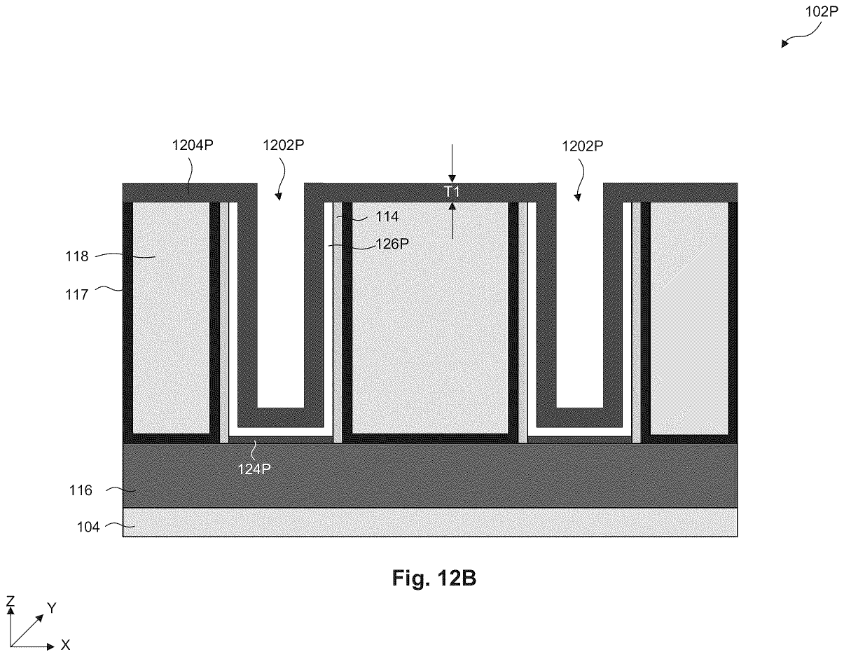

Referring to FIG. 2, in operation 215, gate openings surrounding the first and second sets of nanostructured channel layers are formed. Subsequently, IL layer and dielectric layers are formed in the gate openings. For example, as described with reference to FIGS. 10A, 10B and 10C, gate openings 1002N and 1002P are formed. Gate openings 1002N and 1002P can be formed by removing polysilicon structures 702 and sacrificial layers 302. Subsequently, IL layers 124N can be formed in gate openings 1002N and IL layers 124P can be formed in gate openings 1002P, as shown in FIGS. 11A, 11B and 11C. In some embodiments, IL layers 124N and 124P can be formed by performing a wet oxidation process on the exposed surfaces of nanostructured channel layers 120N and 120P and fin or sheet bases 106N and 106P in gate openings 1002N and 1002P. The wet oxidation process can oxidize top portions of nanostructured channel layers 120N and fin or sheet base 106N to form IL layer 124N and can oxidize top portions of nanostructured channel layers 120P and fin or sheet base 106P to form IL layer 124P.

In some embodiments, the wet oxidation process can include (i) using a mixture (referred to as “Piranha solution”) of sulfuric acid (H₂SO₄) and hydrogen peroxide (H₂O₂) at a temperature of about 60° C. to about 100° C., (ii) using an ozone (O₃) solution of O₃ in DI water, (iii) using a mixture of ammonium hydroxide (NH₄OH) and H₂O₂, and/or (iv) using a mixture of hydrochloric acid (HCl) and H₂O₂. In some embodiments, the wet oxidation process can be followed by a densification process, which can include performing an anneal process on the structures of FIGS. 10A and 10B at a temperature of about 300° C. to about 550° C.

The dielectric layer is deposited on the IL layer and on sidewalls of the the gate openings. For example, as described with reference to FIGS. 11A, 11B and 11C, dielectric layers 126N can be deposited on IL layer 124N in gate opening 1002N to form gate opening 1102N. Similarly, dielectric layer 126P can be deposited on IL layers 124P in gate openings 1002P to form gate opening 1102P. dielectric layers 126N and 126P can extend along sidewalls of gate openings 1102N and 1102P. The deposition of the dielectric layer can include depositing a layer of dielectric material, such as HfO₂, TiO₂, HfZrO, Ta₂O₃, HfSiO₄, ZrO₂, and ZrSiO₂ with a thickness of about 1 nm to about 2 nm. In some embodiments, dielectric layer can be deposited using atomic layer deposition (ALD) process using hafnium chloride (HfCl₄) as a precursor at a temperature of about 250° C. and about 350° C.

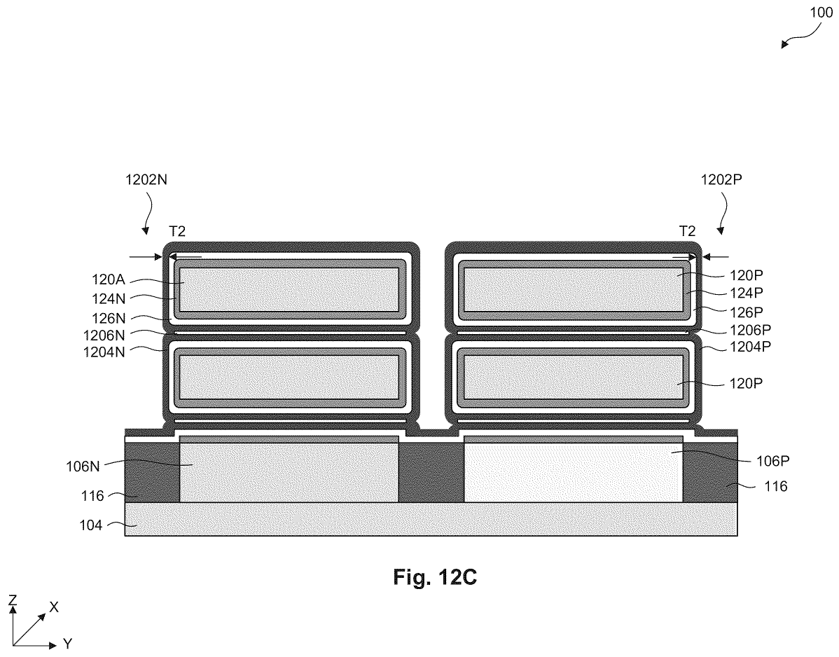

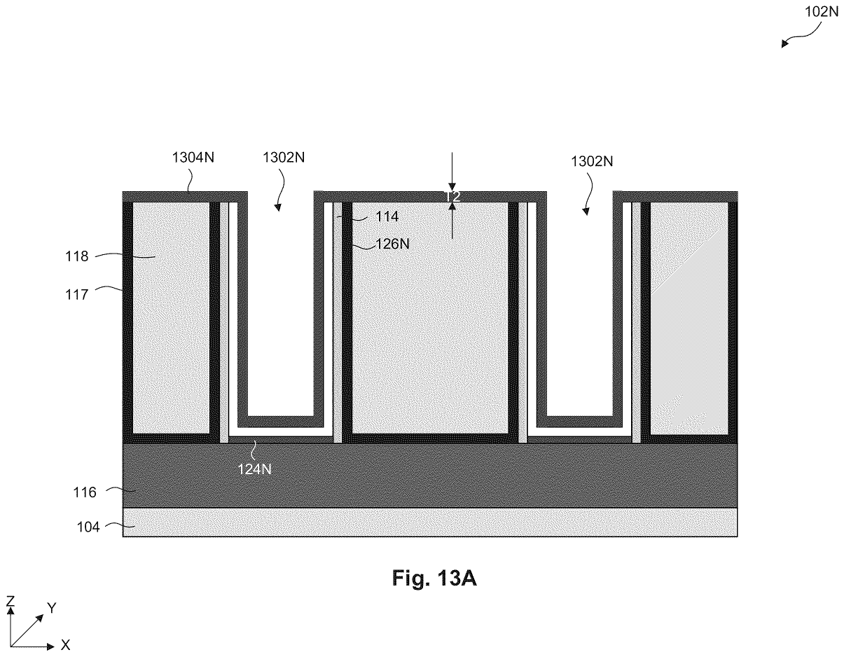

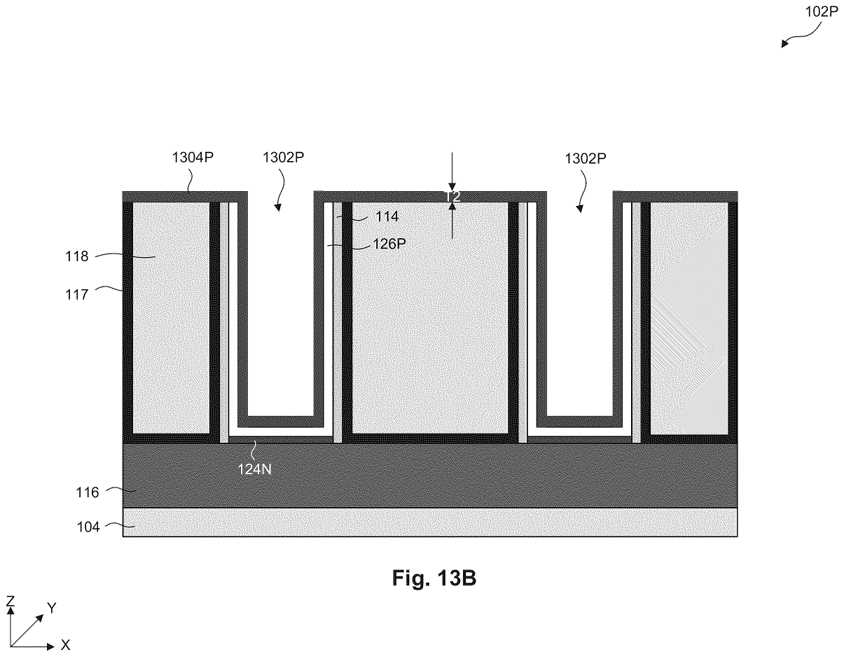

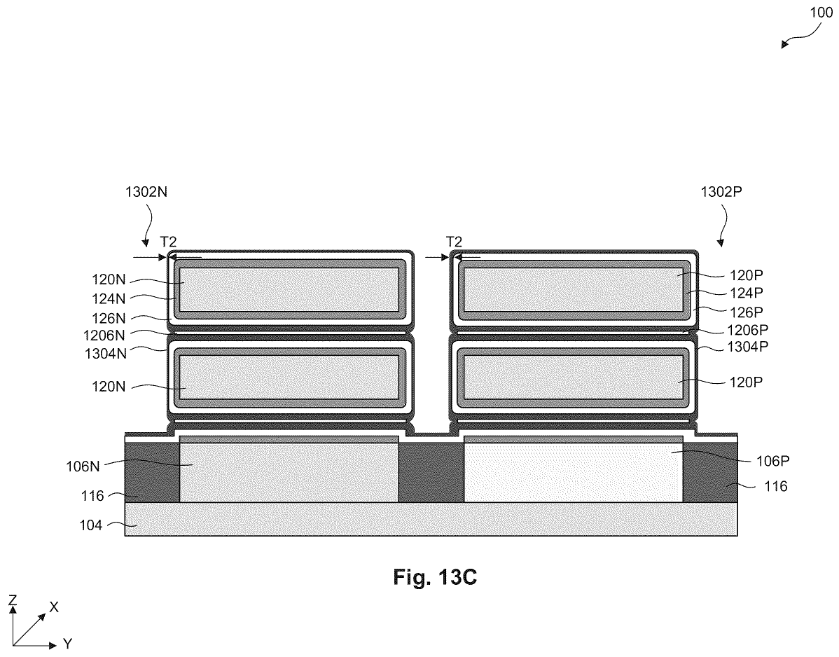

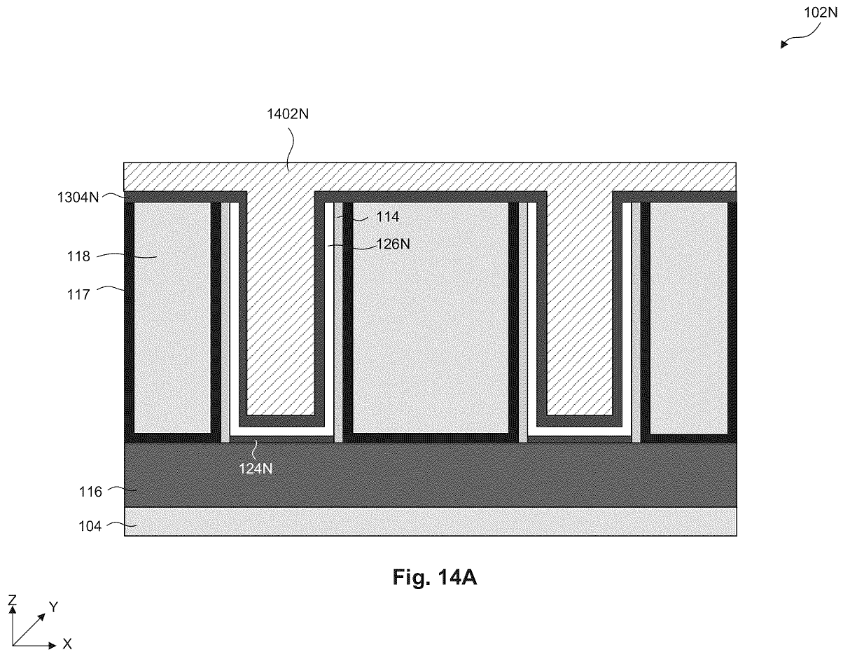

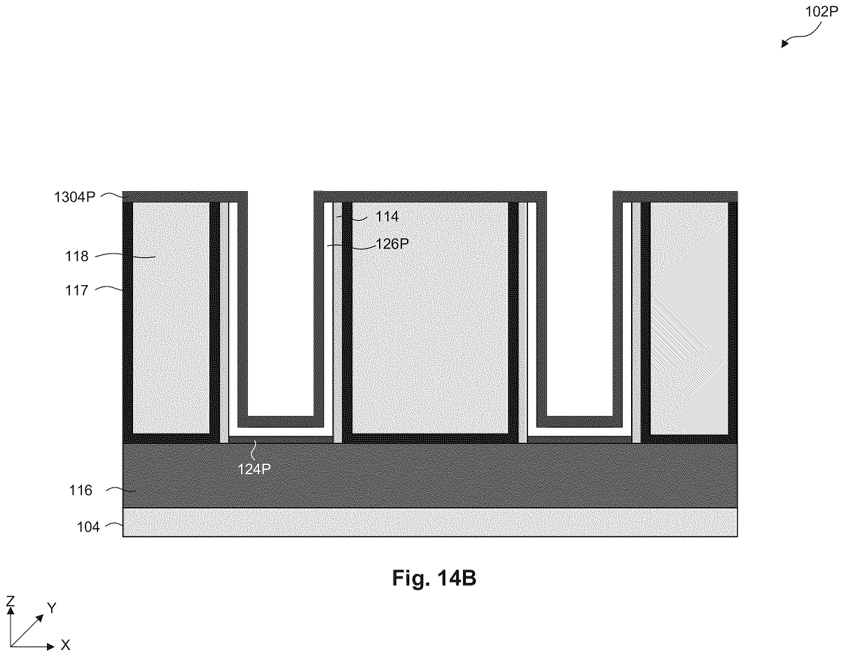

Referring to FIG. 2, in operation 220, a dummy layer is deposited on the dielectric layer in gate openings surrounding on the first and second sets of nanostructured channel layers. Subsequently, the dummy layer formed in gate openings surrounding the second set of nanostructured channel layers is removed. For example, as described with reference to FIG. 12A, dummy layer 1204N can be deposited on dielectric layers 126N in gate openings 1102N. As described with reference to FIG. 12B, dummy layer 1204P can be deposited on dielectric layer 126P in gate openings 1102P. Dummy layers 1204N and 1204P are formed of the same material. As shown in FIG. 12C, dummy layers 1204N and 1204P can have a thickness T1. In some embodiments, dummy layers 1204N and 1204P can be formed of aluminum oxide (Al₂O₃) and can have a thickness T1 between about 27.5 Å and about 35 Å. For example, thickness T1 of the Al₂O₃ dummy layer can be about 32.5 Å. In some embodiments, Al₂O₃ forming the dummy layer can be deposited using ALD. In some embodiments, as shown in FIG. 12C, Al₂O₃ dummy layer 1204N deposited between nanostructured channel layers 120N can enclose an air gap 1206N. Similarly, Al₂O₃ dummy layer 1204P deposited between nanostructured channel layers 120P can enclose an air gap 1206P, as shown in FIG. 12C. Air gaps 1206N and 1206P can also be referred to as seams. Dummy layer (also referred to as “Al₂O₃ dummy layer”) can be deposited in gate openings 1102N and 1102P shown in FIGS. 11A and 11B to form gate openings 1202N and 1202P as shown in FIGS. 12A and 12B.

Dummy layer deposition is followed by a dummy layer etch back process, in which the dummy layer thickness is reduced by etching a portion of the dummy layer. For example, as described with reference to FIGS. 13A, 13B and 13C, dummy layers 1204N and 1204P (shown in FIGS. 12A, 12B and 12C) can be etched to reduce their thickness T1 to form dummy layers 1304N and 1304P with thickness T2. Dummy layers 1304N and 1304P can have a thickness T2 between about 14 Å and about 20 Å. For example, the thickness T2 of the Al₂O₃ dummy layer post etch back processing can be about 17.5 Å. In some embodiments, the etch back process can be a wet etch process. The wet etch process can be performed using ammonium hydroxide (NH₄OH), hydrogen peroxide (H₂O₂), and DI water (H₂O) in the ratio 1:1:5. In some embodiments, the wet etch process can be performed at a temperature of about 50° C. and can have an etch rate of about 0.52 Å/sec. For example, using the wet etch conditions above, an Al₂O₃ dummy layer with an as-deposited thickness of about 32.5 Å can be etched back to about 17 Å in about 30 seconds. Following the etch back process, gate openings 1202N and 1202P can be enlarged to form gate openings 1302N and 1302P as shown in FIGS. 13A and 13B.

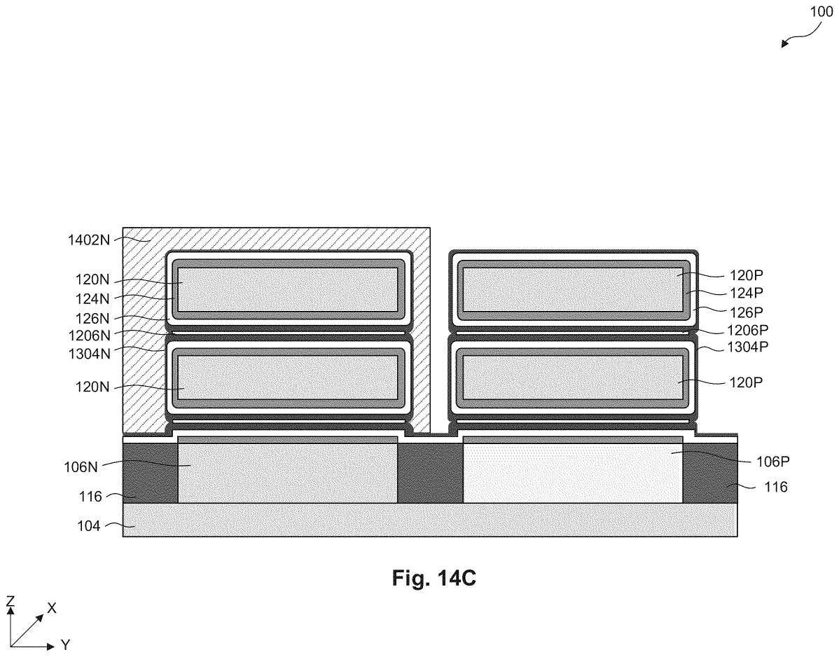

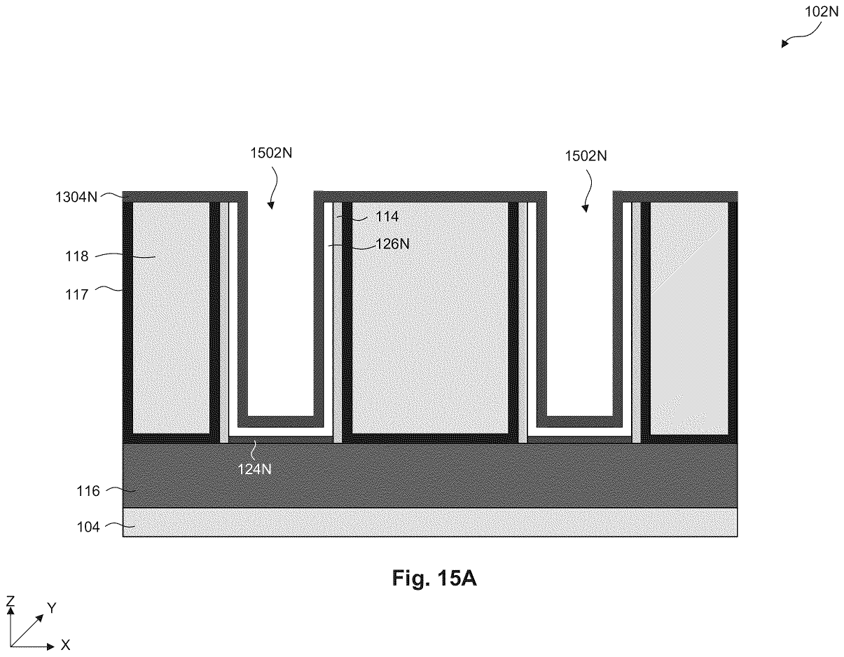

Following the etch back process, a bottom anti-reflectant coating (BARC) along with a photoresist can be deposited on the dummy layer. The BARC and photoresist layer can be deposited on dummy layers 1304N and 1304P. The BARC and photoresist layer can be spin coated to deposit on dummy layers 1304N and 1304P. For example, as described with reference to FIGS. 14A, 14B, and 14C, the BARC and photoresist layer covering dummy layer 1304P can be patterned and subsequently removed using an ashing process. The ashing process can be performed in a nitrogen or hydrogen environment. As shown in FIGS. 14A and 14C, BARC and photoresist layer 1402N can cover dummy layer 1304N. Dummy layer 1304P can be exposed for removal in the next operation.

The exposed dummy layer on the second set of nanostructured channel layers is removed using an etch process. The dummy layer on the first set of nanostructured channel layers remains protected by the BARC and photoresist layer. For example, the etch process can be performed on the structures shown in FIGS. 14A-14C to form structures shown in FIGS. 15A-15C. With reference to FIGS. 15B and 15C, Al₂O₃ dummy layer 1304P can be removed using a wet etch process. In some embodiments, Al₂O₃ dummy layer 1304P can be wet etched using a 1:20 NH₄OH:H₂O solution at about 50° C. In some embodiments, this ammonium hydroxide based wet can etch about 17 Å of Al₂O₃ dummy layer 1304P in about 110 seconds. The ammonium hydroxide based etch is highly selective to the underlying dielectric layer 126P. Post etching, BARC and photoresist layer 1402N can be removed from the NFET region using an ashing process.

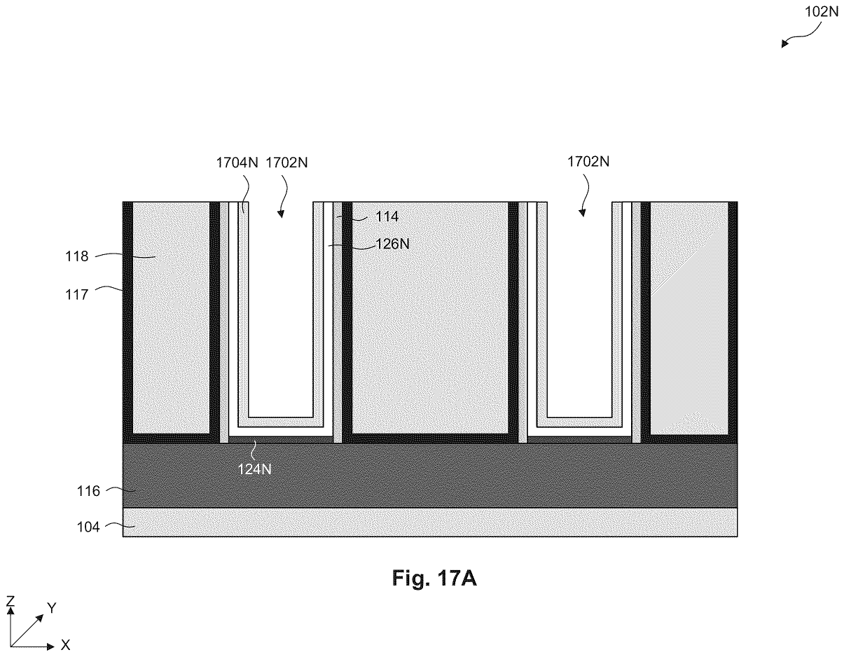

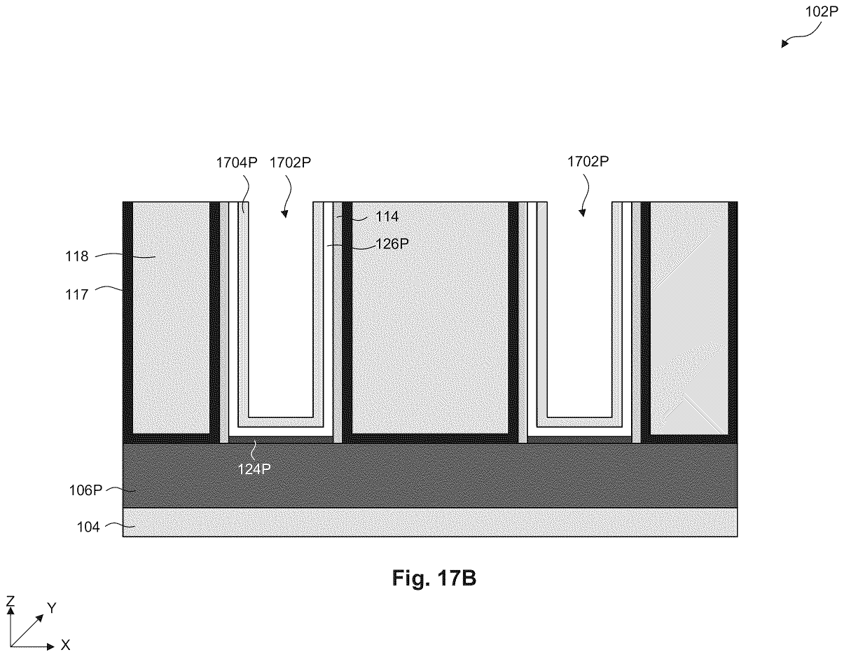

In some embodiments, gate openings may not have vertical sidewalls. Rather, the sidewalls can be sloped and can constrict some portions of the gate openings, thereby creating a necked profile. Further deposition of gate layers can further narrow or constrict the gate opening. Extreme constriction of the gate opening can plug the gate opening. In some embodiments, opening 1502N can have a necked profile as shown in FIG. 15D. This necked profile can be a result of the polysilicon structure etching process. WFM layer 126N and dummy layer 1304N deposited on the sidewalls of necked opening can further exacerbate the necking effect and create a constriction in a lower portion of opening 1502N as shown in FIG. 15D. A bottom portion of opening 1502N and the constriction can form air pocket 1504N as shown in FIG. 15D. Air pockets 1504N can undesirably trap WFM layer 1704N, as shown in FIG. 15E. WFM layer 1704N layers trapped in air pockets 1504N can be difficult to remove. To prevent formation of a necked profile of gate openings 1502N, dummy layer 1304N can be trimmed back to create a larger opening for deposition of WFM layer 1704N. The trim back process can be an etching process. FIG. 15D shows a portion of gate opening 1502N of the structure shown in FIG. 15A. FIG. 15E shows a portion of gate opening 1702N of the structure shown in FIG. 17A.

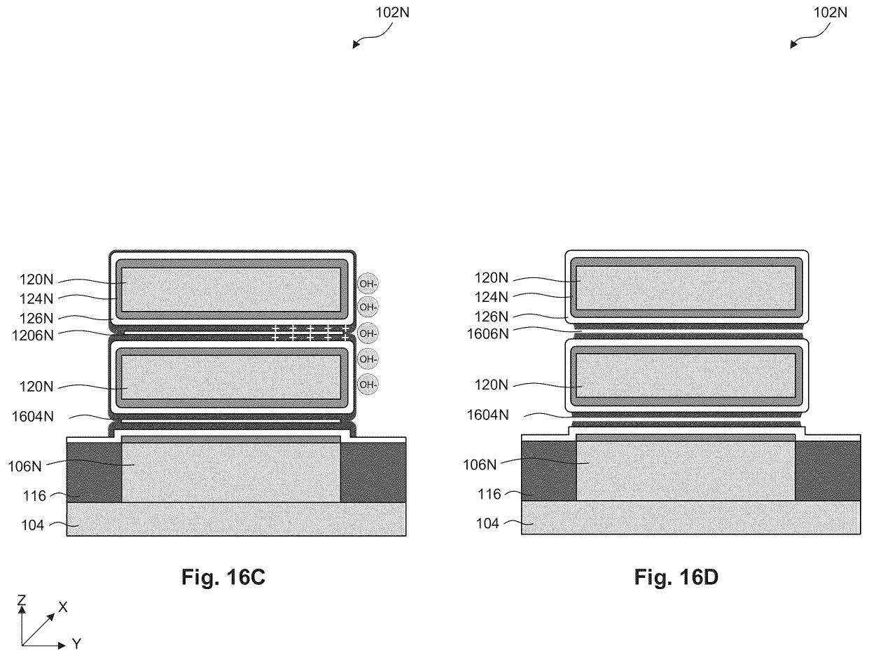

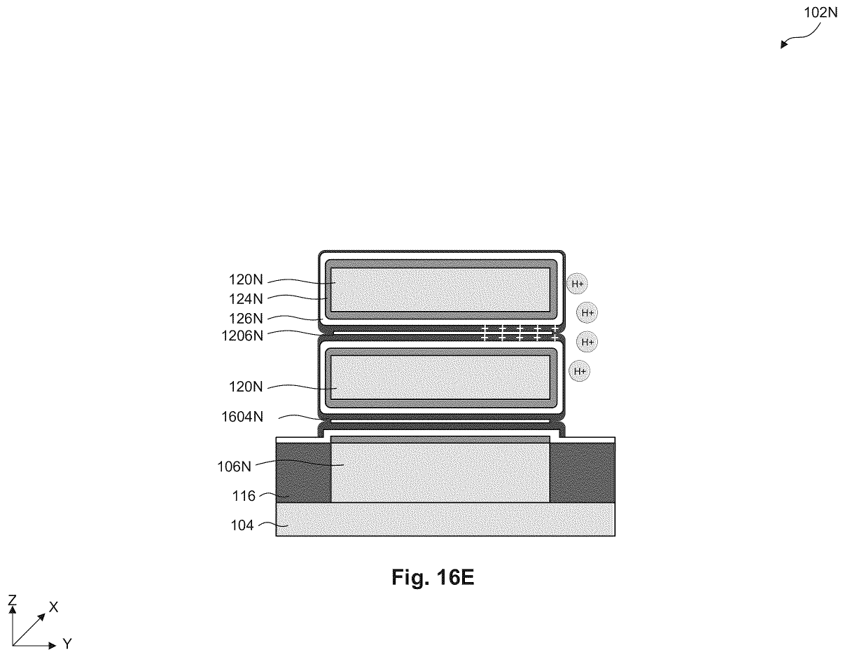

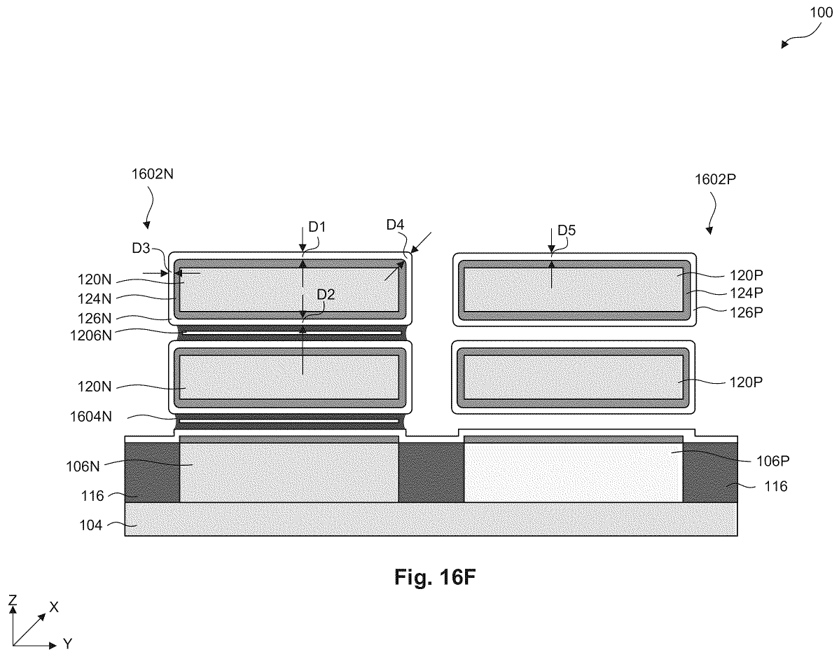

In some embodiments, trimming back the dummy layer can include isotropically wet etching the dummy layer to (i) remove the dummy layer formed on a top surface of the WFM layer formed on the uppermost nanostructured channel layer of the first set of nanostructured channel layers, (ii) remove the dummy layer from side surfaces of the WFM layer on the first set of nanostructured channel layers, and (iii) removing the dummy layer formed on a top surface of the WFM layer disposed on the STI regions. As described with reference to FIGS. 16A and 16F, trimming back dummy layer 1304N includes etching (i) dummy layer 1304N formed on the top surface of the WFM layer 126N on the uppermost nanostructured channel layer of the first set of nanostructured channel layers 120N, (ii) dummy layer 1304N formed on sidewall surfaces of WFM layer 126N on the first set of nanostructured channel layers 120N, and (iii) dummy layer 1304N formed on a top surface of the WFM layer 126N disposed on the STI regions 116. Additionally, dummy layer 1304N disposed on sidewalls of openings 1502N and on top surfaces of dielectric layer 118 and ESL 117 in FIG. 15A can be etched to form the structure in FIG. 16A. At this stage in the fabrication flow, dummy layer 1304P from the PFET region has already been removed as shown in FIGS. 15B and 16B. With reference to FIG. 16F, at the end of the trim back process, dummy layer 1604N with air gap 1206N can be formed (i) between nanostructured channel layers 120N, and (ii) between a bottom-most nanostructured channel layer 120N and fin base 106N.

The trim back etching process can be a hybrid wet etch process involving a first wet etch operation and a second wet etch operation. In some embodiments, the first wet etch operation can be performed using 1:20 NH₄OH: H₂O as an etchant with an NH₄OH concentration between about 0.1 atomic weight % and about 50 atomic weight %. In some embodiments, the first wet etch operation can be performed at room temperature. In some embodiments, the second wet etch operation can be performed using 1:25 hydrochloric acid (HCl):H₂O with an HCl concentration between about 0.1 atomic weight % and about 1.0 atomic weight %. In some embodiments, using the hybrid wet etch process described above, an Al₂O₃ dummy layer about 13 Å in thickness can be trimmed back to OÅ using the hybrid wet etch process including about 30 seconds of the first wet etch operation and about 196 seconds of the second wet etch operation.

In some embodiments, the trim back process can be an HCl wet etch process and can be performed using 1:25 HCl:H₂O as an etchant with an HCl concentration between about 3 atomic weight % and about 12 atomic weight %. In some embodiments, using the HCl wet etch process described above, an Al₂O₃ dummy layer about 13 Å in thickness can be trimmed back to 0 Å in about 315 seconds.

With reference to FIG. 16C, Al₂O₃ dummy layer 1604N holds a positive charge on its surface due to a presence of oxygen vacancies in the Al₂O₃ material. The first wet etch operation using NH₄OH: H₂O as the etchant can remove an outer portion of Al₂O₃ dummy layer 1604N. As the outer portions of Al₂O₃ dummy layer are etched away and the NH₄OH: H₂O comes in contact with inner portions of Al₂O₃ dummy layer 1604N close to air gap 1206N, it is critical to switch the etchant to HCl:H₂O. This is because the OH-ions in NH₄OH can accumulate close to the air gap or seams owing to the positive charge on the Al₂O₃, as shown in FIG. 16C. As shown in FIG. 16D, portions of Al₂O₃ dummy layer 1604N plugging end portions of air gap 1206N can be etched away, opening up air gap 1206N to subsequent WFM layer deposition. The WFM layer can be trapped in the air gap 1606N and can be difficult to remove during a WFM layer etch. Therefore, it is critical that air gaps 1206N do not open up during the trim back etching process.

After removing outer portions of Al₂O₃ dummy layer 1604N, the structure in FIG. 16C undergoes the second wet etch operation that uses diluted HCl (HCl:H₂O in the ratio 1:25). During the second wet etch operation, the H+ ions from HCl are replled by the positive charge on Al₂O₃ dummy layer 1604N as shown in FIG. 16E. This prevents the portions of Al₂O₃ dummy layer 1604N plugging end portions of air gap 1206N from being etched, thereby preventing air gap 1206N from opening. At the end of the second wet etch operation, the structure in FIG. 16F can be formed with dummy layer 1604N between nanostructured channel layers 120N. Dummy layer 1604N prevents the WFM layer from depositing in spaces between nanostructured channel layers 120N.

Referring to FIG. 2, in operation 225, the work function layer is deposited on the dielectric layer in gate openings surrounding the first and second sets of nanostructured channel layers. For example, WFM layer 1704N can be deposited on dielectric layer 126N in gate openings 1602N of FIG. 16A form the structures shown in FIGS. 17A and 17C. Similarly, WFM layer 128P can be can be deposited on dielectric layer 126P in gate openings 1602P of FIG. 16B to form the structures shown in FIGS. 17B and 17C. Gate openings 1702N and 1702P can be formed after deposition of WFM layers 1704N and 128P in gate openings 1602N and 1602P, respectively. WFM layers 1704N and 1704N can be composed of a same material and can be deposited using chemical vapor deposition (CVD) or ALD. In some embodiments, WFM layer formed of titanium nitride (TiN) material layer with a thickness of about 30 Å can be deposited using ALD.

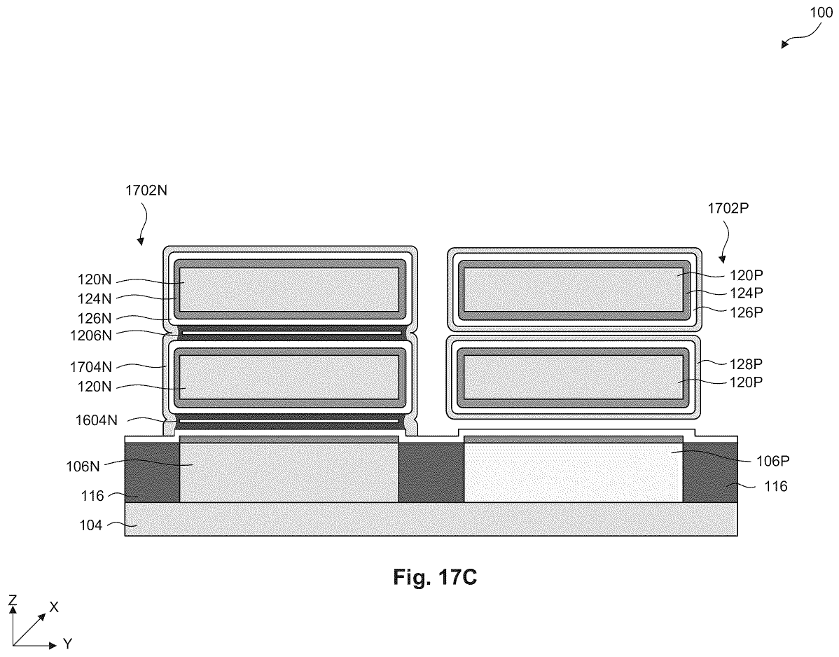

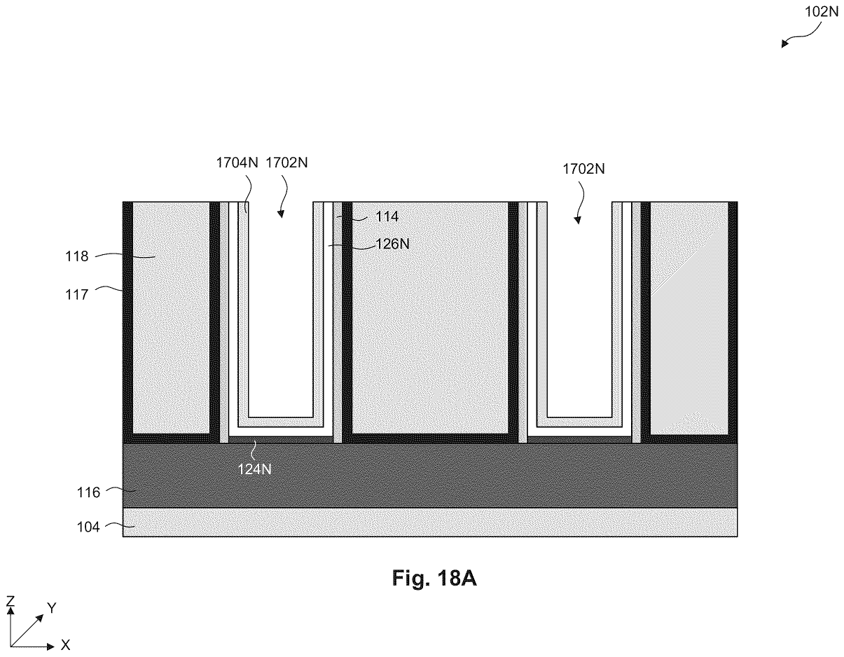

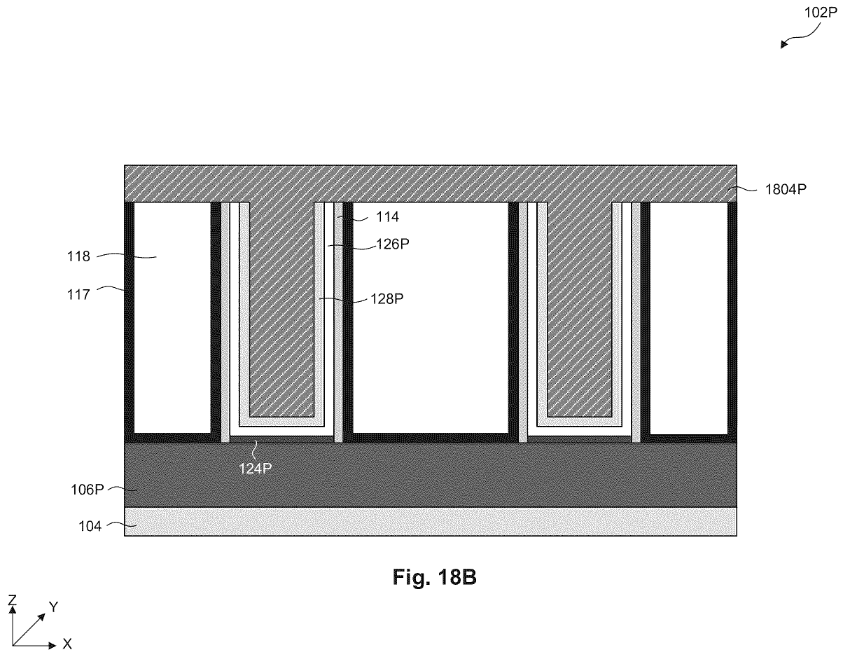

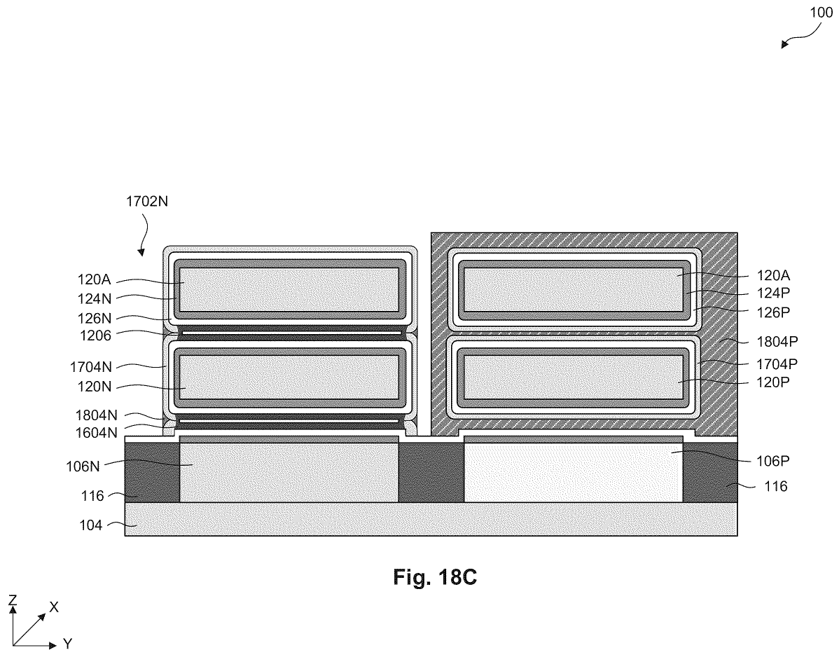

Referring to FIG. 2, in operation 230, WFM layer from gate openings surrounding the first set of nanostructured channel layers is removed and the WFM layer in gate openings surrounding the second set of nanostructured channel layers is retained. For example, as described with reference to FIG. 18B, to prevent removal of WFM layer 126P surrounding the second set of nanostructured channel layers 120P, BARC and photoresist layer 1804P can be formed in gate openings 1702P. BARC and photoresist layer 1804P can be formed by (i) spin coating a BARC and photoresist layer to fill gate openings 1702N and 1702P, and (ii) patterning and removing the BARC and photoresist layer from gate openings 1702N using an ash process using at least one of argon (Ar), hydrogen (H₂), methane (CH₄), or nitrogen (N₂). As shown in FIG. 18B, BARC and photoresist layer 1804P fills gate openings 1702P and covers top surfaces of WFM layer 1702P, dielectric layer 126P, outer spacer 114, ESL 117, and ILD layer 118. As shown in FIGS. 18A and 18C, the BARC and photoresist layer do not fill gate openings 1702N exposing WFM layer 1704N. In some embodiments, polymer residue 1804N from photoresist and BARC deposition and removal can be formed in notches between nanostructured channel layers 120N.

Subsequently, the polymer residue, the WFM layer and the dummy layer in gate openings surrounding the first set of nanostructured channel layers are removed. For example, as described with reference to FIGS. 19A and 19C, polymer residue 1804N, WFM layer 1704N, and Al₂O₃ dummy layer 1604N can be removed by etching. In some embodiments, polymer residue 1804N can be removed by an SC₂ (Standard Clean 2) wet etch process using 1:10:50 of HCl:H₂O₂:H₂O. For example, polymer residue 1804N can be removed using SC₂ wet etch at about 50° C. in about 84 seconds. Subsequently, WFM layer 1704N can be etched using a peroxide based wet etch process. In some embodiments, WFM layer 1704N can be etched using 1:5 of H₂O₂:H₂O solution at about 50° C. in about 70 seconds. In some embodiments, WMF layer 1704N can form an interfacial layer at an interface between WFM layer 1704N and Al₂O₃ dummy layer 1604N (not shown). Prior to removal of the dummy layer, this interfacial layer needs to be removed. In some embodiments, the interfacial layer can be removed using a second SC₂ wet etch process using 1:10:50 of HCl:H₂O₂:H₂O. In some embodiments, the interfacial layer can be removed using SC₂ wet etch at about 50° C. in about 70 seconds.

Post interfacial layer removal, dummy layer 1604N can be removed using an ammonium hydroxide based wet etch process. In some embodiments, dummy layer 1604N can be etched using 1:20::NH₄OH: H₂O at about 50° C., in about 258 seconds to form the structure shown in FIG. 19A. Subsequently, BARC and photoresist layer 1804P covering second set of nanostructured channel layers 120P can be removed using an ashing process to form the structure shown in FIG. 19B. Ashing can be performed in an Ar, N₂, H₂, or CH₄ environment.

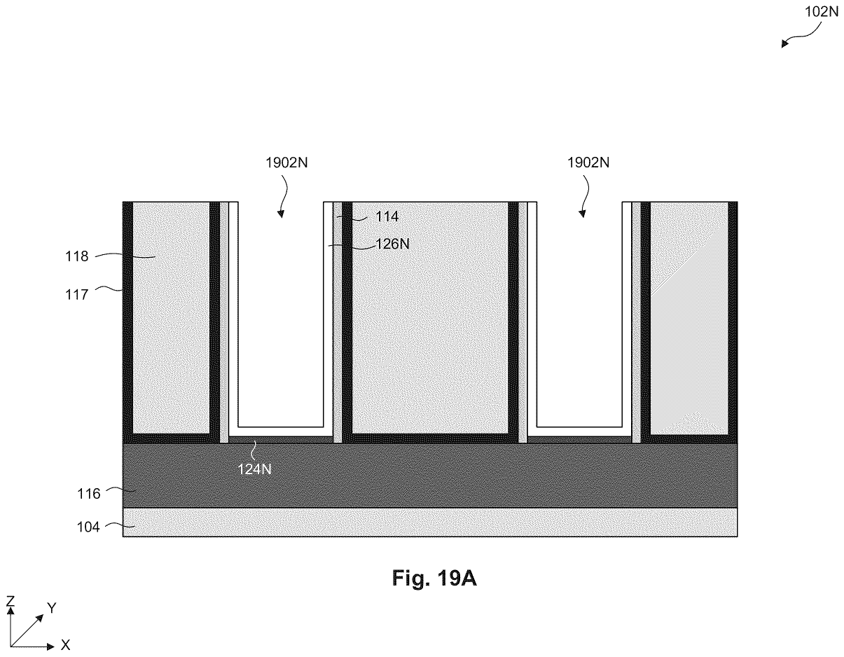

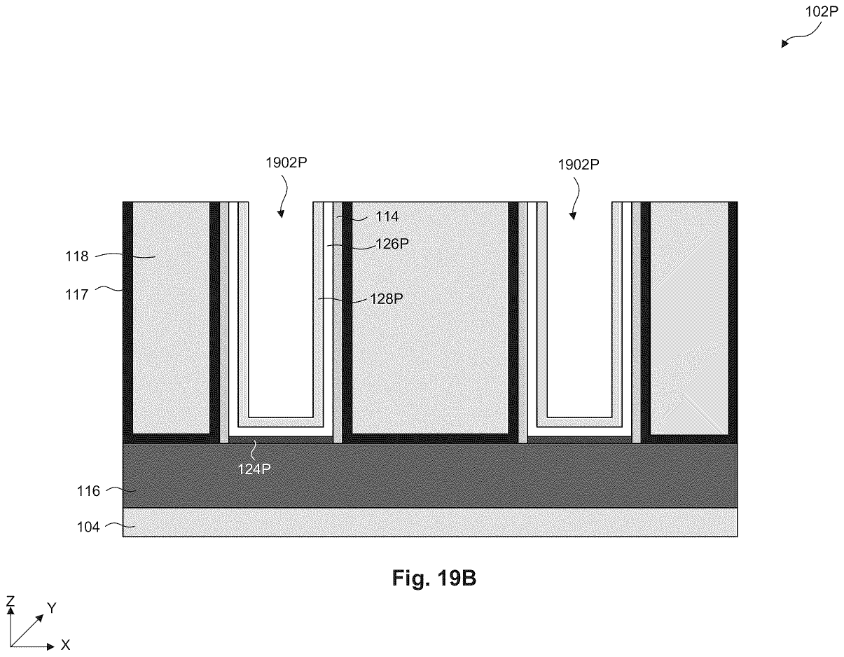

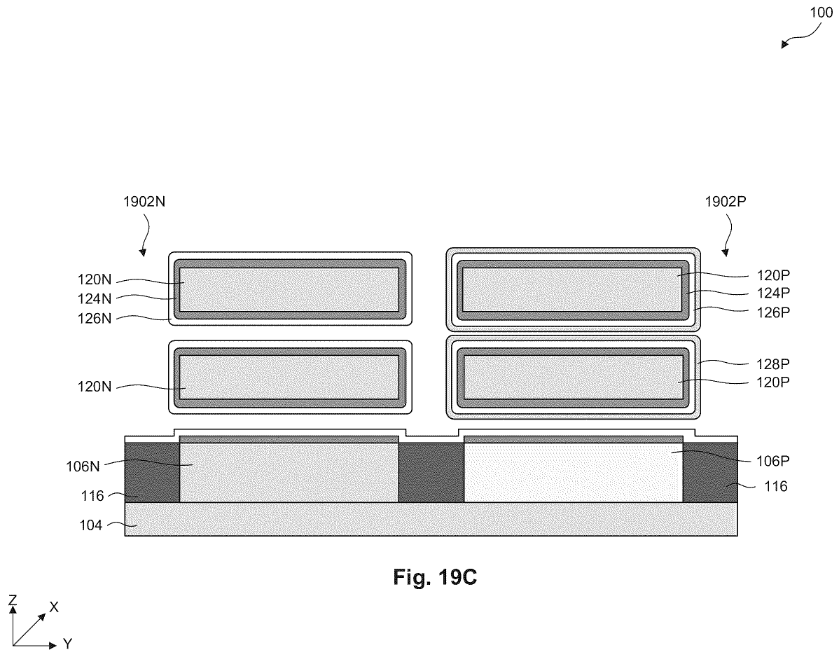

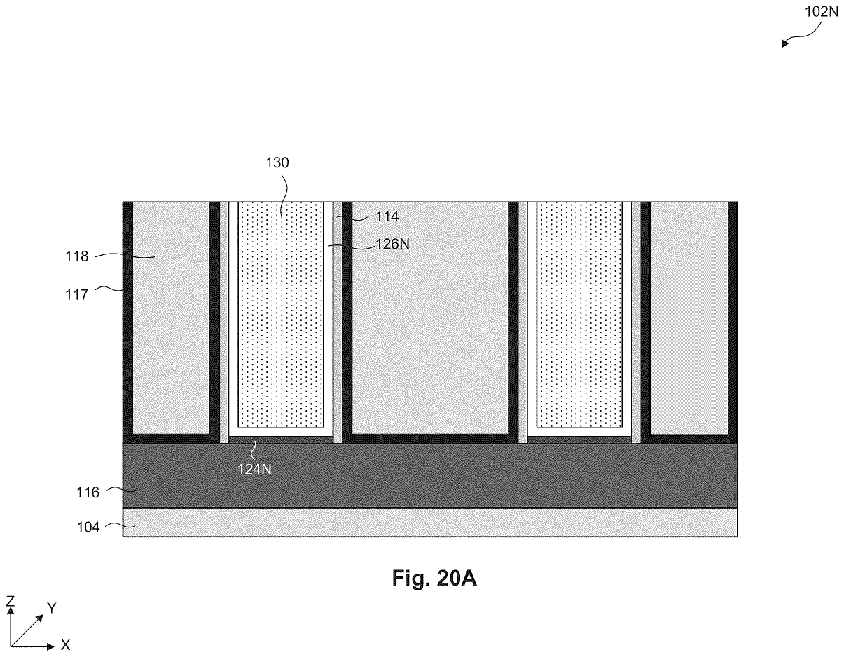

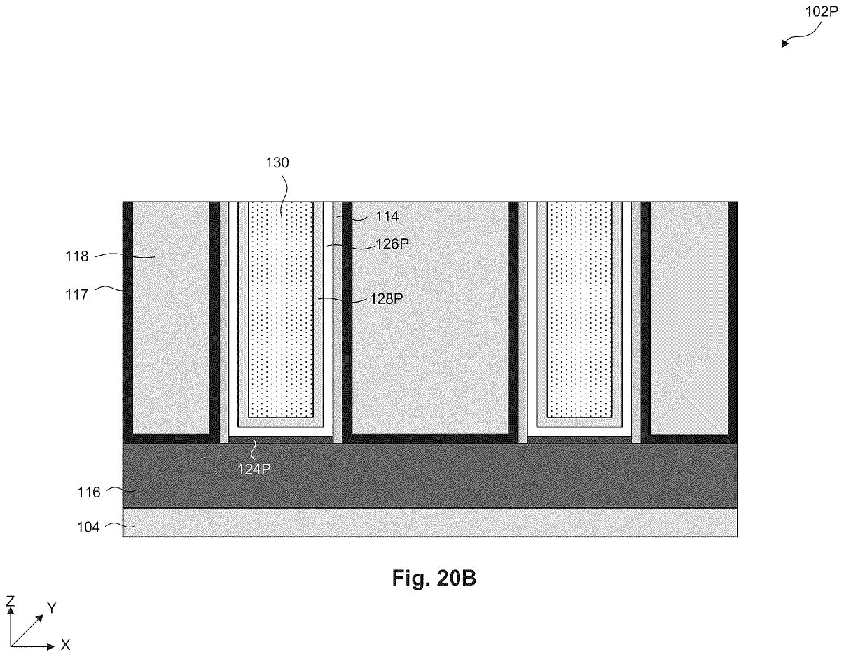

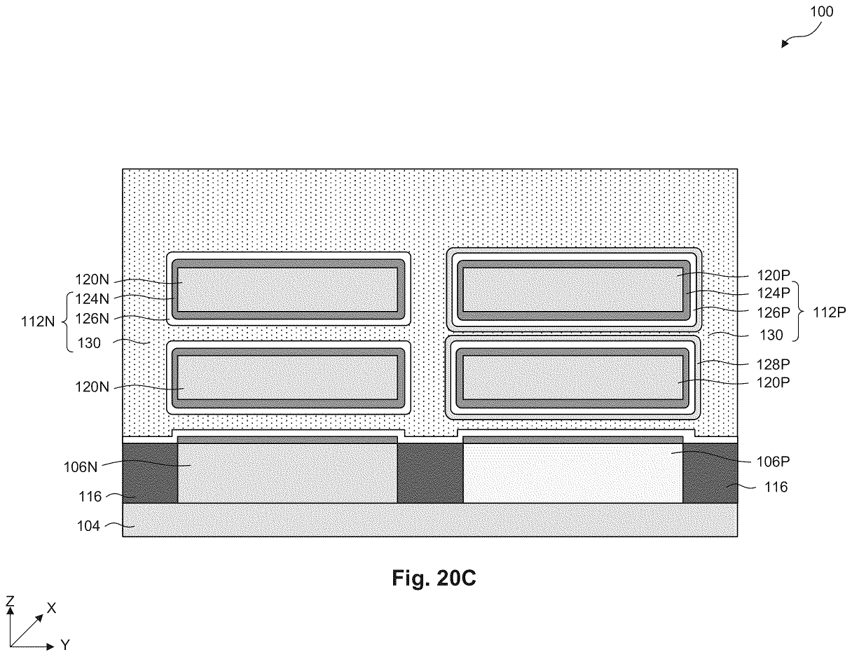

Referring to FIG. 2, in operation 235, gate metal fill can be (i) deposited on the dielectric layer in gate openings surrounding the first set of nanostructured channel layers, and (ii) on the WFM layer in gate openings surrounding the second set of nanostructured channel layers. For example, gate metal fill layer 130 can be deposited on (i) dielectric layer 126N in gate openings 1902N shown in FIGS. 19A and 19C, and (ii) WFM layer 128P in gate openings 1902P shown in FIGS. 19B and 19C. Gate metal fill layer 130 can be deposited on top surfaces of dielectric layer 118 and ESL 117. Subsequently, gate metal fill layer 130 can be chemical mechanical polished to substantially co-planarize a top surface of gate metal fill layer 130 with top surfaces of dielectric layer 118 and ESL 117 to form the structures shown in FIGS. 20A-20C.

The present disclosure provides a method for forming NFET 102N with gate electrode stack 112N without a WFM layer and PFET 102P with gate electrode stack 112P with WFM layer 128P. The method includes forming first set of nanostructured channel layers 120N and second set of nanostructured channel layers 120P for fabricating NFET 102N and PFET 102P, respectively. Dummy layer 1206N is formed between first set of nanostructured channel layers 120N to prevent deposition of WFM layer between first set of nanostructured channel layers 120N in subsequent operations. WFM layers 1704N and 1704P are deposited to surround first and second set of nanostructured channel layers 120N and 120P, respectively. WFM layer 128P surrounding second set of nanostructured channel layers 120P is protected using protective layer 1804P. WFM layer 1704N and the dummy layer 1206N surrounding first set of nanostructured channel layers 120N is removed. Gate metal fill layer 130 is subsequently deposited to form gate electrodes of NFET 102N and PFET 102P.

In some embodiments, a method includes forming a first set of nanostructured channel layers and a second set of nanostructured channel layers on a substrate, and etching gate openings surrounding the first and second sets of nanostructured channel layers. The method can further includes forming an oxide layer and a dielectric layer in the gate openings, and depositing a dummy layer in the gate openings surrounding the first and second sets of nanostructured channel layers. In some embodiments, a first portion of the dummy layer from the gate openings surrounding the first set of nanostructured channel layers and removing the dummy layer from the gate openings surrounding the second set of nanostructured channel layers can be removed. Subsequently, depositing a work function layer on the dielectric layer in the gate openings can be deposited. In some embodiments, removing the work function layer and a second portion of the dummy layer from the gate openings surrounding the first set of nanostructured channel layers can be removed and a gate metal fill layer can be deposited on the dielectric layer surrounding the first set of nanostructured channel layers and on the work function layer surrounding the second set of nanostructured channel layers

In some embodiments, a method includes forming a first plurality of nanostructured channel layers on a substrate, forming a second plurality of nanostructured channel layers on the substrate, and etching gate openings surrounding the first and second pluralities of nanostructured channel layers. In some embodiments, an oxide layer can be formed on exposed surfaces of the first and second pluralities of nanostructured channel layers and a dielectric layer can be deposited on the oxide layer. In some embodiments, a dummy layer can be formed between nanostructured channel layers of the first plurality of nanostructured channel layers. Subsequently, a work function metal layer can be formed in the gate openings surrounding the first and second pluralities of nanostructured channel layers, the work function layer can be removed from the gate openings surrounding the first plurality of nanostructured channel layers, and the dummy layer formed between the nanostructured channel layers of the first plurality of nanostructured channel layers can be removed.

In some embodiments, a semiconductor device includes a first transistor including a first set of nanostructured channel layers disposed on a substrate and a first gate structure surrounding the first set of nanostructured channel layers. In some embodiments, the first gate structure can include a first oxide layer formed on exposed surfaces of the first set of nanostructured channel layers, a first dielectric layer in contact with the first oxide layer, a work function layer in contact with the first dielectric layer, and a gate contact layer in contact with the work function layer. The semiconductor device can also include a second transistor include a second set of nanostructured channel layers disposed on the substrate and a second gate structure surrounding the second set of nanostructured channel layers. In some embodiments, the second gate structure can include a second oxide layer formed on exposed surfaces of the second set of nanostructured channel layers, a second dielectric layer in contact with the second oxide layer, and the gate contact layer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first set of nanostructured channel layers and a second set of nanostructured channel layers on a substrate;
etching gate openings surrounding the first and second sets of nanostructured channel layers;
forming a dielectric layer in the gate openings;
depositing a dummy layer in the gate openings surrounding the first and second sets of nanostructured channel layers;
removing a first portion of the dummy layer from the gate openings surrounding the first set of nanostructured channel layers and removing the dummy layer from the gate openings surrounding the second set of nanostructured channel layers;
depositing a work function layer on the dielectric layer in the gate openings;
removing the work function layer and a second portion of the dummy layer from the gate openings surrounding the first set of nanostructured channel layers; and
depositing gate metal fill layer on the dielectric layer surrounding the first set of nanostructured channel layers and on the work function layer surrounding the second set of nanostructured channel layers.

2. The method of claim 1, wherein depositing the dummy layer comprises depositing a layer of aluminum oxide.

3. The method of claim 1, further comprising removing the dummy layer from a top surface and side surfaces of the first set of nanostructured channel layers prior to depositing the work function layer.

4. The method of claim 1, further comprising reducing a thickness of the dummy layer by isotopically etching the dummy layer prior to etching the dummy layer from the second set of nanostructured channel layers.

5. The method of claim 4, wherein isotopically etching the dummy layer comprises:
etching a first portion of the dummy layer using a first etchant comprising ammonium hydroxide; and
etching a second portion of the dummy layer using a second etchant comprising hydrochloric acid.

6. The method of claim 1, further comprising:
depositing a protective layer to cover the first and second sets of nanostructured channel layers;
patterning the protective layer; and
removing the protective layer from the second set of nanostructured channel layers to expose the work function layer.

7. The method of claim 6, further comprising removing a protective layer residue from side surfaces between adjacent nanostructured channel layers of the first set of nanostructured channel layers using a peroxide based solution.

8. A method, comprising:
forming a first plurality of nanostructured channel layers on a substrate;
forming a second plurality of nanostructured channel layers on the substrate;
etching gate openings surrounding the first and second pluralities of nanostructured channel layers;
depositing a dielectric layer within the gate openings;
forming a dummy layer between nanostructured channel layers of the first plurality of nanostructured channel layers;
depositing work function metal layer in the gate openings surrounding the first and second pluralities of nanostructured channel layers;
removing the work function layer from the gate openings surrounding the first plurality of nanostructured channel layers; and
removing the dummy layer formed between the nanostructured channel layers of the first plurality of nanostructured channel layers.

9. The method of claim 8, wherein forming the dummy layer between the nanostructured channel layers of the first plurality of nanostructured channel layers comprises etching the dummy layer from a top surface and sidewall surfaces of the dielectric layer on the first plurality of nanostructured channel layers.

10. The method of claim 8, wherein forming the dummy layer between the nanostructured channel layers of the first plurality of nanostructured channel layers comprises:
depositing the dummy layer on the dielectric layer in the gate openings surrounding the first and second pluralities of nanostructured channel layers;
etching the dummy layer; and
removing the dummy layer in the gate openings surrounding the second plurality of nanostructured channel layers.

11. The method of claim 8, further comprising depositing a gate fill material on the dielectric layer in the gate openings surrounding the first plurality of nanostructured channel layers.

12. The method of claim 8, further comprising depositing a gate fill material on the work function metal layer in the gate openings surrounding the second plurality of nanostructured channel layers.

13. The method of claim 8, wherein forming the dummy layer between nanostructured channel layers of the first plurality of nanostructured channel layers comprises:
etching a first portion of the dummy layer using a first etchant comprising ammonium hydroxide; and
etching a second portion of the dummy layer using a second etchant comprising hydrochloric acid.

14. The method of claim 8, wherein removing the work function layer comprises etching the work function layer using a peroxide based wet etch process.

15. The method of claim 8, wherein removing the dummy layer formed between nanostructured channel layers of the first plurality of nanostructured channel layers comprises etching the dummy layer using an ammonium hydroxide based wet etch process.

16. The method of claim 8, wherein forming the dummy layer between nanostructured channel layers of the first plurality of nanostructured channel layers comprises:
depositing the dummy layer on the dielectric layer covering the first and second pluralities of nanostructured channel layers;
protecting the dummy layer deposited on the first plurality of nanostructured channel layers using a protective layer; and
etching the dummy layer deposited on the second plurality of nanostructured channel layers.

17. The method of claim 16, wherein etching the dummy layer deposited on the second plurality of nanostructured channel layers comprises etching the dummy layer using an ammonium hydroxide based wet etch process.

18. A device, comprising:
a first transistor comprising:
a first set of nanostructured channel layers disposed on a substrate; and
a first gate structure surrounding the first set of nanostructured channel layers and comprising:
a first oxide layer formed on exposed surfaces of the first set of nanostructured channel layers;
a first dielectric layer in contact with the first oxide layer;
a work function layer in contact with the first dielectric layer; and
a gate contact layer in contact with the work function layer; and
a second transistor comprising:
a second set of nanostructured channel layers disposed on the substrate; and
a second gate structure surrounding the second set of nanostructured channel layers comprising:
a second oxide layer formed on exposed surfaces of the second set of nanostructured channel layers; and
a second dielectric layer in contact with the second oxide layer and the gate contact layer, wherein
the second dielectric layer is on a top surface of an uppermost nanostructured channel layer of the second set of nanostructured channel layers and has a first thickness,
the second dielectric layer is disposed on a bottom surface of the uppermost nanostructured channel layer of the second set of nanostructured channel layers and has a second thickness, and
the second thickness is greater than the first thickness.

19. The device of claim 18, wherein a difference between the second thickness and the first thickness is between about 0.1 nm and about 0.7 nm.

20. The device of claim 19, wherein a sidewall surface of the second dielectric layer on the uppermost nanostructured channel layer of the second set of nanostructured channel layers has a thickness substantially equal to the first thickness.
